(19) United States
(12) Patent Application Publication
(10) Pub. No.: US 2023/0320151 A1
(43) Pub. Date: Oct. 5, 2023

(54) DISPLAY APPARATUS

(71) Applicant: SAMSUNG DISPLAY CO., LTD., Yongin-si (KR)

(72) Inventor: Chulhyun CHOI, Yongin-si (KR)

(21) Appl. No.: 18/105,874

(22) Filed: Feb. 5, 2023

(30) Foreign Application Priority Data
Apr. 5, 2022 (KR) 10-2022-0042523

(51) Int. Cl. H10K 59/131; G09G 3/3233; H10K 59/80

(52) U.S. Cl. CPC H10K 59/131; G09G 3/3233; H10K 59/80515; G09G 2300/0842; G09G 2300/0819; G09G 2320/0666

(57) ABSTRACT

A display apparatus includes a substrate and a first pixel electrode disposed over the substrate, where a distance from a first portion of an upper surface of the first pixel electrode to an upper surface of the substrate is greater than a distance from a second portion of the upper surface of the first pixel electrode to the upper surface of the substrate.

This application claims priority to Korean Patent Application No. 10-2022-0042523, filed on Apr. 5, 2022, and all the benefits accruing therefrom under 35 U.S.C. § 119, the content of which in its entirety is herein incorporated by reference.

### BACKGROUND

### 1. Field

One or more embodiments relate to a display apparatus, and more particularly, to a display apparatus with improved display quality.

### 2. Description of the Related Art

An organic light-emitting display apparatus includes an organic light-emitting element as a display element. The organic light-emitting element may include a pixel electrode, an opposite electrode, and an intermediate layer between the pixel electrode and the opposite electrode and including an emission layer. In addition, the organic light-emitting display apparatus may include an electronic element and/or line configured to control an electrical signal transmitted to the organic light-emitting element.

### SUMMARY

In a conventional organic light-emitting display apparatus, images of a same color coordinate may be differently recognized, depending on a viewing angle from which the display apparatus is viewed.

One or more embodiments include a display apparatus with improved image quality. However, the one or more embodiments are only examples, and the scope of the present disclosure is not limited thereto.

According to one or more embodiments, a display apparatus includes a substrate, and a first pixel electrode disposed over the substrate, where a distance from a first portion of an upper surface of the first pixel electrode to an upper surface of the substrate is greater than a distance from a second portion of the upper surface of the first pixel electrode to the upper surface of the substrate.

In an embodiment, the display apparatus may further include a data line disposed over the substrate and extending in a first direction, and an insulation layer covering the data line, where the first pixel electrode may be disposed over the insulation layer, and, when viewed from a direction perpendicular to the substrate, a line connecting a central portion of the first portion of the upper surface of the first pixel electrode and a central portion of the second portion of the upper surface of the first pixel electrode may form an acute angle with the first direction.

In an embodiment, when viewed from the direction perpendicular to the substrate, the line connecting the central portion of the first portion of the upper surface of the first pixel electrode and the central portion of the second portion of the upper surface of the first pixel electrode may form an angle of about 45 degrees with the first direction.

In an embodiment, when viewed from the direction perpendicular to the substrate, the central portion of the second portion of the upper surface of the first pixel electrode may be positioned closer to the data line than the central portion of the first portion of the upper surface of the first pixel electrode, and the central portion of the second portion of the upper surface of the first pixel electrode may be positioned in the first direction from the central portion of the first portion of the upper surface of the first pixel electrode.

In an embodiment, the display apparatus may further include a first conductive layer disposed on a layer on which the data line is disposed, where the insulation layer may cover the first conductive layer, and, when viewed from the direction perpendicular to the substrate, the first conductive layer may correspond to the first portion of the upper surface of the first pixel electrode.

In an embodiment, when viewed from the direction perpendicular to the substrate, the first conductive layer may not overlap the second portion of the upper surface of the first pixel electrode.

In an embodiment, when viewed from the direction perpendicular to the substrate, the first conductive layer may have a chamfered line extending in a direction crossing the line connecting the central portion of the first portion of the upper surface of the first pixel electrode and the central portion of the second portion of the upper surface of the first pixel electrode to each other.

In an embodiment, when viewed from the direction perpendicular to the substrate, the chamfered line may be perpendicular to the line connecting the central portion of the first portion of the upper surface of the first pixel electrode and the central portion of the second portion of the upper surface of the first pixel electrode to each other.

In an embodiment, the display apparatus may further include a data line disposed over the substrate and extending in a first direction, an insulation layer covering the data line, a second pixel electrode disposed over the insulation layer, and a pixel-defining layer covering an edge of each of the first pixel electrode and the second pixel electrode, where the first pixel electrode may be disposed over the insulation layer, and, when viewed from a direction perpendicular to the substrate, a line connecting a central portion of the first portion of the upper surface of the first pixel electrode and a central portion of the second portion of the upper surface of the first pixel electrode may form an acute angle with the first direction.

In an embodiment, the display apparatus may further include a first conductive layer and a second conductive layer disposed on a layer on which the data line is disposed, where the insulation layer covers the first conductive layer and the second conductive layer, and, when viewed from the direction perpendicular to the substrate, the first conductive layer may correspond to the first portion of the upper surface of the first pixel electrode, and the second conductive layer may correspond to the second pixel electrode.

In an embodiment, when viewed from the direction perpendicular to the substrate, the first conductive layer may not overlap the second portion of the upper surface of the first pixel electrode, and a length of the second conductive layer in the first direction may be equal to a length, in the first direction, of an exposed portion of the second pixel electrode, which is not covered with the pixel-defining layer.

In an embodiment, when viewed from the direction perpendicular to the substrate, the first conductive layer may not overlap the second portion of the upper surface of the first pixel electrode, and an end of the second conductive layer in the first direction may be aligned with an end, in the first direction, of a portion of the second pixel electrode not covered with the pixel-defining layer, and an end of the second conductive layer in a direction opposite to the first direction may be aligned with an end, in the direction opposite to the first direction, of the exposed portion of the second pixel electrode, which is not covered with the pixel-defining layer.

In an embodiment, when viewed from the direction perpendicular to the substrate, the first conductive layer may not overlap the second portion of the upper surface of the first pixel electrode, and a length of the second conductive layer in the first direction may be greater than a length, in the first direction, of an exposed portion of the second pixel electrode, which is not covered with the pixel-defining layer.

In an embodiment, when viewed from the direction perpendicular to the substrate, the first conductive layer may not overlap the second portion of the upper surface of the first pixel electrode, and an end of the second conductive layer in the first direction may be aligned with an end, in the first direction, of an exposed portion of the second pixel electrode, which is not covered with the pixel-defining layer, and an end of the second conductive layer in a direction opposite to the first direction may be aligned with an end, in the direction opposite to the first direction, of the exposed portion of the second pixel electrode, which is not covered with the pixel-defining layer.

In an embodiment, when viewed from the direction perpendicular to the substrate, the first conductive layer may not overlap the second portion of the upper surface of the first pixel electrode, and an end of the second conductive layer in the first direction may be positioned outside of an end, in the first direction, of an exposed portion of the second pixel electrode, which is not covered with the pixel-defining layer, and an end of the second conductive layer in a direction opposite to the first direction may correspond to an end, in the direction opposite to the first direction, of the exposed portion of the second pixel electrode, which is not covered with the pixel-defining layer.

In an embodiment, when viewed from the direction perpendicular to the substrate, the first conductive layer may not overlap the second portion of the upper surface of the first pixel electrode, and an end of the second conductive layer in the first direction may be positioned outside of an end, in the first direction, of an exposed portion of the second pixel electrode, which is not covered with the pixel-defining layer, and an end of the second conductive layer in a direction opposite to the first direction may be positioned outside of an end, in the direction opposite to the first direction, of the exposed portion of the second pixel electrode, which is not covered with the pixel-defining layer.

In an embodiment, when viewed from the direction perpendicular to the substrate, the first conductive layer may have a chamfered line extending in a direction crossing the line connecting the central portion of the first portion of the upper surface of the first pixel electrode and the central portion of the second portion of the upper surface of the first pixel electrode.

In an embodiment, when viewed from the direction perpendicular to the substrate, the chamfered line may be perpendicular to the line connecting the central portion of the first portion of the upper surface of the first pixel electrode and the central portion of the second portion of the upper surface of the first pixel electrode.

In an embodiment, when viewed from the direction perpendicular to the substrate, the line connecting the central portion of the first portion of the upper surface of the first pixel electrode and the central portion of the second portion of the upper surface of the first pixel electrode may form an angle of about 45 degrees with the first direction.

In an embodiment, when viewed from the direction perpendicular to the substrate, the central portion of the second portion of the upper surface of the first pixel electrode may be positioned closer to the data line than the central portion of the first portion of the upper surface of the first pixel electrode, and the central portion of the second portion of the upper surface of the first pixel electrode may be positioned in the first direction from the central portion of the first portion of the upper surface of the first pixel electrode.

### BRIEF DESCRIPTION OF THE DRAWINGS

The above and other features of certain embodiments will be more apparent from the following description taken in conjunction with the accompanying drawings, in which:

FIG. 1 is a plan view schematically illustrating a portion of a display apparatus according to an embodiment;

FIG. 2 is an equivalent circuit diagram of a pixel included in the display apparatus in FIG. 1;

FIG. 3 is a plan view schematically illustrating positions of transistors, capacitors, or the like in pixels included in the display apparatus in FIG. 1;

FIGS. 4 to 11 are plan views schematically illustrating elements, such as transistors and capacitors, of the display apparatus shown in FIG. 3 for each layer;

FIG. 12 is a cross-sectional view schematically illustrating cross-sections of the display apparatus shown in FIG. 3, taken along lines I-I′, and III-Ill′;

FIG. 13 is a cross-sectional view schematically illustrating a cross-section of the display apparatus shown in FIG. 11, taken along line IV-IV′;

FIG. 14 is a graph schematically illustrating a change in luminance according to a change in viewing angle in the display apparatus shown in FIG. 13 and in a display apparatus according to a comparative example;

FIG. 15 is a graph schematically illustrating a change in color coordinates according to a change in viewing angle in a display apparatus according to a comparative example;

FIG. 16 is a plan view schematically illustrating some layers of a display apparatus according to an embodiment;

FIG. 17 is a plan view schematically illustrating some layers of a display apparatus according to an embodiment;

FIG. 18 is a plan view schematically illustrating some layers of a display apparatus according to an embodiment;

FIG. 19 is a plan view schematically illustrating some layers of a display apparatus according to an embodiment;

FIG. 20 is a cross-sectional view schematically illustrating a cross-section of the display apparatus shown in FIG. 19, taken along line V-V′;

FIG. 21 is a plan view schematically illustrating some layers of a display apparatus according to an embodiment;

FIG. 22 is a plan view schematically illustrating some layers of a display apparatus according to an embodiment;

FIG. 23 is a plan view schematically illustrating some layers of a display apparatus according to an embodiment;

FIG. 24 is a plan view schematically illustrating some layers of a display apparatus according to an embodiment;

FIG. 25 is a plan view schematically illustrating some layers of a display apparatus according to an embodiment; and

FIG. 26 is a plan view schematically illustrating some layers of a display apparatus according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or expression “at least one selected from a, b and c” indicates only a, only b, only c, both a and b, both a and c, both b and c, all of a, b, and c, or variations thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It will be understood that when an element, such as a layer, a film, a region, or a plate, is referred to as being “on” another element, the element can be directly on the other element or intervening elements may be present thereon. Sizes of elements in the drawings may be exaggerated or reduced for convenience of description. In other words, since sizes and thicknesses of elements in the drawings are arbitrarily illustrated for convenience of explanation, the following embodiments are not limited thereto.

In the following embodiments, the x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another. Herein, the positive and negative directions of the x-axis may be referred to as +x direction and −x direction, respectively, and the positive and negative directions of the y-axis may be referred to as +y direction and −y direction, respectively.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings. The elements in embodiments that are the same as or corresponding to each other are labeled with the same or like reference numerals or characters, and any repetitive detailed descriptions thereof may be omitted or simplified.

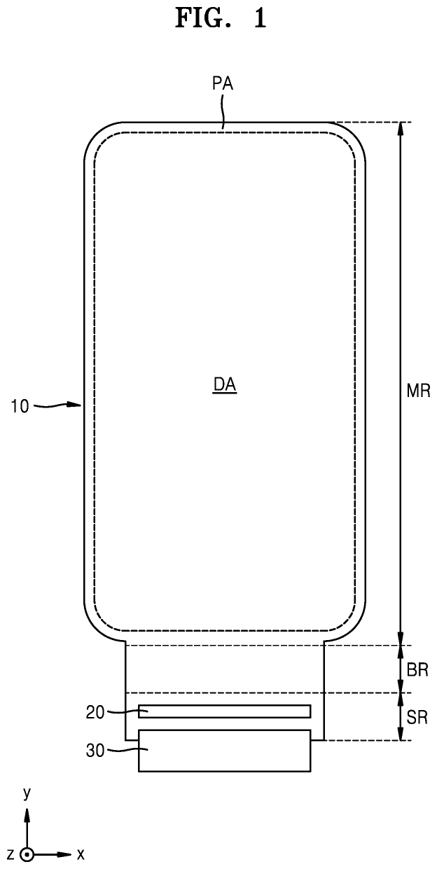

FIG. 1 is a plan view schematically illustrating a portion of a display apparatus according to an embodiment.

As shown in FIG. 1, the display apparatus according to an embodiment may include a display panel 10. The display apparatus may be any display apparatus that includes the display panel 10. In an embodiment, for example, the display apparatus may include various products, such as smartphones, tablet personal computers (PCs), laptop PCs, televisions, or advertisement boards.

The display panel 10 may include a display area DA and a peripheral area PA outside the display area DA. The display area DA may include a portion in which an image is displayed, and a plurality of pixels may be arranged in the display area DA. When viewed from a direction approximately perpendicular to the display panel 10 (i.e., a thickness direction of the display panel 10 or the z-axis direction), the display panel 10 may have various shapes, such as a circle, an ellipse, a polygon, or a particular figure. In an embodiment, as shown in FIG. 1, the display area DA may have a rectangular shape with round edges.

The peripheral area PA may be arranged outside the display area DA. The width (or a length in the x-axis direction) of a portion of the peripheral area PA may be less than the width (or a length in the x-axis direction) of the display area DA. In an embodiment having such a structure, at least a portion of the peripheral area PA may be easily bendable, as described later.

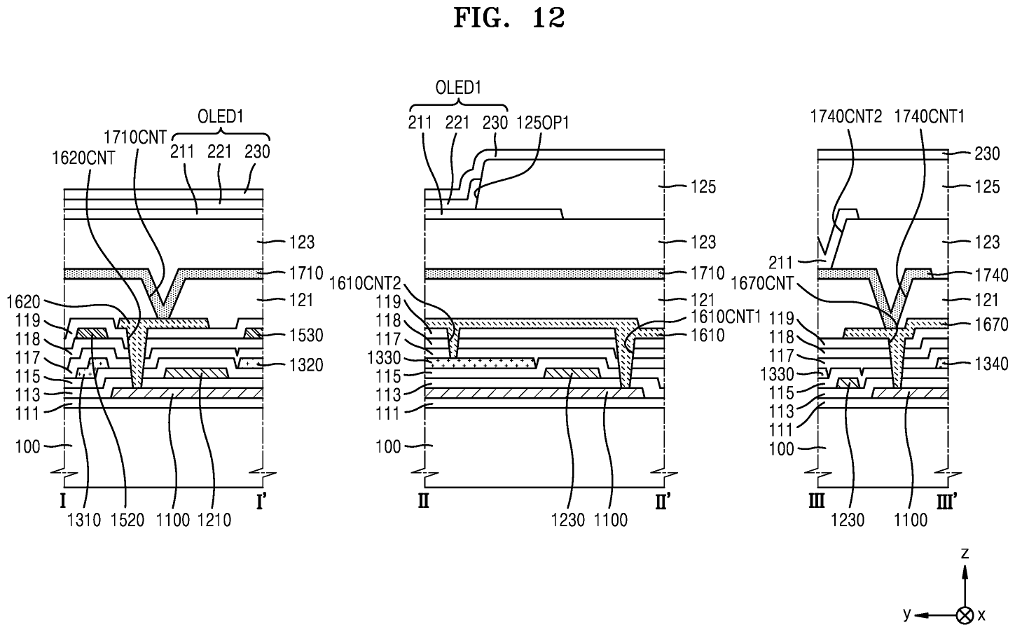

In an embodiment where the display panel 10 includes a substrate 100 (see FIG. 12), the substrate 100 may also be considered as including the display area DA and the peripheral area PA. Hereinafter, it is described that the substrate 100 includes the display area DA and the peripheral area PA, for convenience of description.

In an embodiment, it may be described that the display panel 10 may have a main area MR, a bending area BR, and a sub-area SR, where the bending area BR is outside the main area MR, and the sub-area SR is at an opposite side of the main area MR with respect to the bending area BR. The display panel 10 may be bent in the bending area BR so that at least a portion of the sub-area SR may overlap the main area MR when viewed from the z-axis direction. However, the disclosure is not limited to a bendable display apparatus and may be applicable to a display apparatus that is not bendable. The sub-area SR may include a non-display area. By bending the display panel 10 in the bending area BR, when the display apparatus is viewed from the front (in the −z direction), the non-display area may not be visible, and even in a case in which the non-display area is visible, the visible area of the non-display area may be minimized.

A driving chip 20 or the like may be arranged in the sub-area SR of the display panel 10. The driving chip 20 may include an integrated circuit configured to drive the display panel 10. The integrated circuit may a data driving integrated circuit configured to generate a data signal, but the present disclosure is not limited thereto.

The driving chip 20 may be mounted in the sub-area SR of the display panel 10. The driving chip 20 is mounted on a same surface (or plane) as a display surface of the display area DA, but when the display panel 10 is bent in the bending area BR, as described above, the driving chip 20 may be positioned on the rear surface of the main area MR.

A printed circuit board 30 or the like may be attached to an end of the sub-area SR of the display panel 10. The printed circuit board 30 or the like may be electrically connected to the driving chip 20 or the like through a pad (not shown) on the substrate.

Hereinafter, for convenience of description, embodiment where the display apparatus is an organic light-emitting display apparatus will be described in detail, but the display apparatus of the disclosure is not limited thereto. In an alternative embodiment, the display apparatus of the disclosure may include a display apparatus, such as an inorganic light-emitting display apparatus (an inorganic light-emitting display or an inorganic electroluminescent (EL) display) or a quantum dot light-emitting display. For example, an emission layer of the display element included in the display apparatus may include an organic material or an inorganic material. In addition, the display apparatus may have an emission layer and a quantum dot layer positioned on a path of light emitted from the emission layer.

As described above, the display panel 10 may include the substrate 100. Various elements included in the display panel 10 may be disposed over the substrate 100. The substrate 100 may include glass, metal, or polymer resin. In an embodiment where the display panel 10 is bent in the bending area BR, as described above, the substrate 100 may be flexible or bendable. In such an embodiment, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate. However, the substrate 100 may have a multi-layer structure including two layers and a barrier layer therebetween, each of the two layers may include polymer resin, and the barrier layer may include an inorganic material, such as silicon oxide, silicon nitride, or silicon oxynitride, and various modifications may be made.

A plurality of pixels may be in the display area DA. Each of the pixels refers to a sub-pixel and may include a display element, such as an organic light-emitting diode OLED. In an embodiment, for example, each of the pixels may emit red, green, blue, or white light.

The pixels may be electrically connected to outer circuits arranged in the peripheral area PA. A scan driving circuit, an emission control driving circuit, a terminal, a driving power supply line, an electrode power supply line, and the like may be arranged in the peripheral area PA. The scan driving circuit may be configured to transmit a scan signal to the pixels via a scan line. The emission control driving circuit may be configured to transmit an emission control signal to the pixels via an emission control line. The terminal, which is arranged in the peripheral area PA of the substrate 100, may be exposed by not being covered with an insulation layer, and electrically connected to the printed circuit board 30. A terminal of the printed circuit board 30 may be electrically connected to the terminal of the display panel 10.

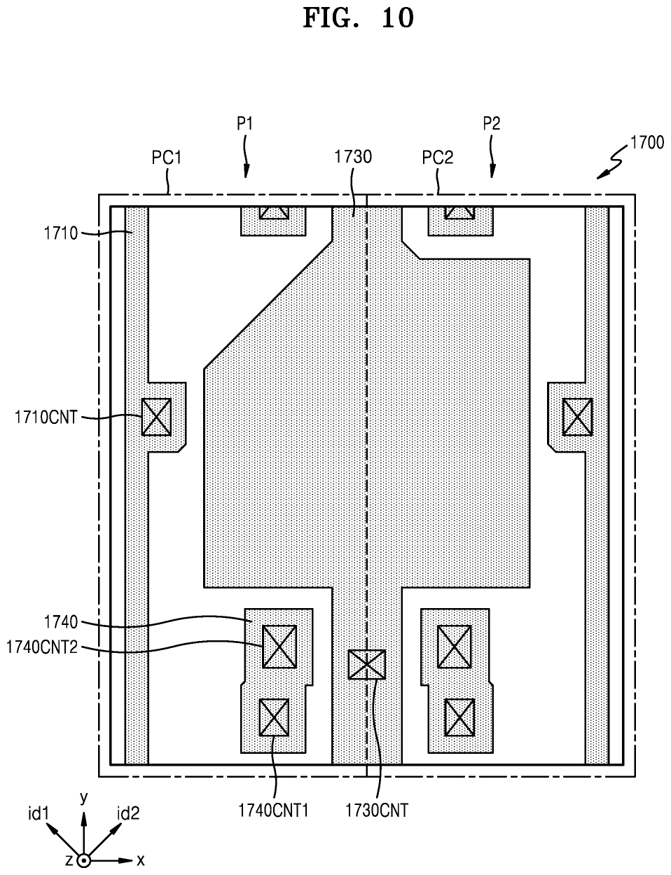

The printed circuit board 30 may transfer a signal or power of a control unit (not shown) to the display panel 10. A control signal generated by the control unit may be transferred to driving circuits via the printed circuit board 30. In addition, the control unit may apply a first power voltage ELVDD to the driving power supply line and apply a second power voltage ELVSS to the electrode power supply line. The first power voltage ELVDD (or driving voltage) may be applied to each of the pixels via a driving power supply line 1730 (see FIG. 10) connected to the driving power supply line, and the second power voltage ELVSS (or common voltage) may be applied to an opposite electrode 230 (see FIG. 12) of a pixel connected to the electrode power supply line. The electrode power supply line may have a loop shape with one side open, and may have a shape partially surrounding the display area DA.

In an embodiment, the control unit may generate a data signal, and the generated data signal may be transmitted to the pixels via the driving chip 20 and a data line 1710 (see FIG. 10).

For reference, the term “line” may refer to “wiring” in the embodiments described herein.

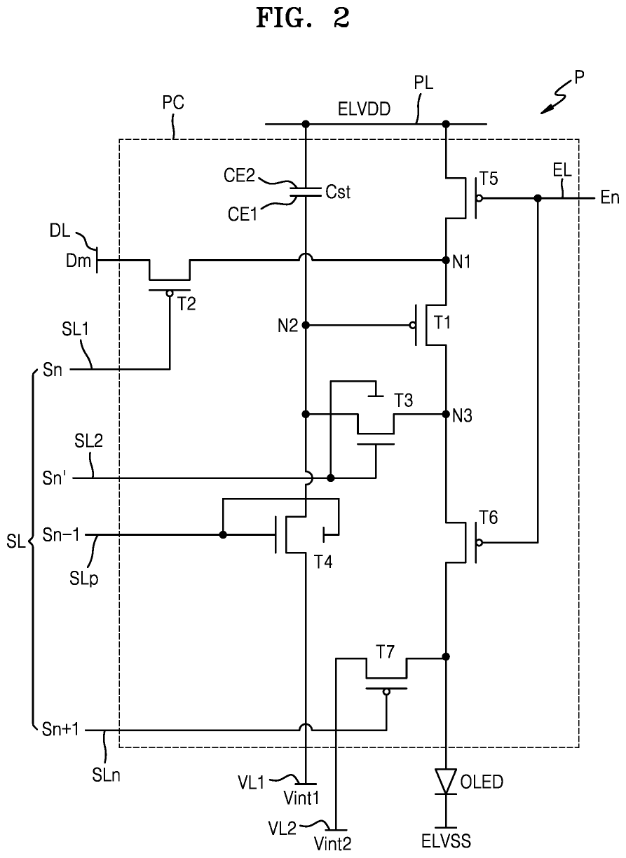

FIG. 2 is an equivalent circuit diagram of a pixel P included in the display apparatus in FIG. 1. In an embodiment, as shown in FIG. 2, the pixel P may include a pixel circuit PC and an organic light-emitting diode OLED electrically connected to the pixel circuit PC.

The pixel circuit PC may include a plurality of thin-film transistors T1 to T7 and a storage capacitor Cst, as shown in FIG. 2. The plurality of thin-film transistors T1 to T7 and the storage capacitor Cst may be connected to signal lines SL1, SL2, SLp, SLn, EL, and DL, a first initialization voltage line VL1, a second initialization voltage line VL2, and a driving voltage line PL. At least one selected from these lines, for example, the driving voltage line PL, may be shared by neighboring pixels P.

The plurality of thin-film transistors T1 to T7 may include a driving transistor T1, a switching transistor T2, a compensation transistor T3, a first initialization transistor T4, an operation control transistor T5, an emission control transistor T6, and a second initialization transistor T7.

The organic light-emitting diode OLED may include a pixel electrode and an opposite electrode, where the pixel electrode may be connected to the driving transistor T1 via the emission control transistor T6 and receive a driving current, and the opposite electrode may receive the second power voltage ELVSS. The organic light-emitting diode OLED may generate light of a luminance corresponding to the driving current.

Some of the plurality of thin-film transistors T1 to T7 may be n-channel metal-oxide-semiconductor field-effect-transistors (n-channel MOSFETs; NMOS), and the other ones may be p-channel MOSFETs (PMOS). In an embodiment, for example, the compensation transistor T3 and the first initialization transistor T4 from among the plurality of thin-film transistors T1 to T7 may be NMOS, and the other ones may be PMOS. In some embodiments, the compensation transistor T3, the first initialization transistor T4, and the second initialization transistor T7 from among the plurality of thin-film transistors T1 to T7 may be NMOS, and the other ones may be PMOS. In some embodiments, the plurality of thin-film transistors T1 to T7 may all be NMOS or all be PMOS. Each of the plurality of thin-film transistors T1 to T7 may include amorphous silicon or polysilicon. In an embodiment, a thin-film transistor as an NMOS may include an oxide semiconductor. Hereinafter, embodiments where the compensation transistor T3 and the first initialization transistor T4 are NMOS including an oxide semiconductor, and the other ones are PMOS will be described, for convenience of description.

The signal lines may include a first scan line SL1 configured to transmit a first scan signal Sn to the switching transistor T2, a second scan line SL2 configured to transmit a second scan signal Sn′ to the compensation transistor T3, a previous scan line SLp configured to transmit a previous scan signal Sn−1 to the first initialization transistor T4, a next scan line SLn configured to transmit a next scan signal Sn+1 to the second initialization transistor T7, an emission control line EL configured to transmit an emission control signal En to the operation control transistor T5 and the emission control transistor T6, and a data line DL which crosses the first scan line SL1 and is configured to transmit a data signal Dm to the switching transistor T2.

The driving voltage line PL may be configured to transmit the driving voltage ELVDD to the driving transistor T1, the first initialization voltage line VL1 may be configured to transmit a first initialization voltage Vint1 to the first initialization transistor T4 for initializing the driving transistor T1, and the second initialization voltage line VL2 may be configured to transmit a second initialization voltage Vint2 to the second initialization transistor T7 for initializing the pixel electrode of the organic light-emitting diode OLED.

A driving gate electrode of the driving transistor T1 may be connected to the storage capacitor Cst via a second node N2, where one selected from a source region and a drain region of the driving transistor T1 may be connected to the driving voltage line PL via the operation control transistor T5 and a first node N1, and the other of the source region and the drain region of the driving transistor T1 may be electrically connected to the pixel electrode of the organic light-emitting diode OLED via the emission control transistor T6 and a third node N3. The driving transistor T1 may receive the data signal Dm based on a switching operation of the switching transistor T2 and supply a driving current to the organic light-emitting diode OLED. In such an embodiment, the driving transistor T1 may control an amount of current that flows to the organic light-emitting diode OLED from the first node N1 electrically connected to the driving voltage line PL, in response to a voltage applied to the second node N2 that varies according to the data signal Dm.

A switching gate electrode of the switching transistor T2 may be connected to the first scan line SL1 configured to transmit the first scan signal Sn, where one of a source region and a drain region of the switching transistor T2 may be connected to the data line DL, and the other of the source region and the drain region of the switching transistor T2 may be connected to the driving voltage line PL via the operation control transistor T5 and to the driving transistor T1 via the first node N1. In response to a voltage applied to the first scan line SL1, the switching transistor T2 may be configured to transmit the data signal Dm from the data line DL to the first node N1. In such an embodiment, the switching transistor T2 may be turned on in response to the first scan signal Sn via the first scan line SL1 and perform a switching operation for transmitting the data signal Dm received via the data line DL to the driving transistor T1 via the first node N1.

A compensation gate electrode of the compensation transistor T3 may be connected to the second scan line SL2. One of a source region and a drain region of the compensation transistor T3 may be connected to the pixel electrode of the organic light-emitting diode OLED via the emission control transistor T6 and the third node N3. The other of the source region and the drain region of the compensation transistor T3 may be connected to a first capacitor electrode CE1 of the storage capacitor Cst and the driving gate electrode of the driving transistor T1 via the second node N2. The compensation transistor T3 as described above may be turned on in response to the second scan signal Sn′ received via the second scan line SL2 and diode-connect the driving transistor T1.

A first initialization gate electrode of the first initialization transistor T4 may be connected to the previous scan line SLp. One of a source region and a drain region of the first initialization transistor T4 may be connected to the first initialization voltage line VL1. The other of the source region and the drain region of the first initialization transistor T4 may be connected to the first capacitor electrode CE1 of the storage capacitor Cst and the driving gate electrode of the driving transistor T1 via the second node N2. The first initialization transistor T4 may be configured to apply the first initialization voltage Vint1 to the second node N2 from the first initialization voltage line VL1, in response to a voltage applied to the previous scan line SLp. In such an embodiment, the first initialization transistor T4 may be turned on in response to the previous scan signal Sn−1 received via the previous scan line SLp and perform an initialization operation for applying the first initialization voltage Vint1 to the driving gate electrode of the driving transistor T1 and initializing a voltage of the driving gate electrode of the driving transistor T1.

An operation control gate electrode of the operation control transistor T5 may be connected to the emission control line EL, where one of a source region and a drain region of the operation control transistor T5 may be connected to the driving voltage line PL, and the other of the source region and the drain region of the operation control transistor T5 may be connected to the driving transistor T1 and the switching transistor T2 via the first node N1.

An emission control gate electrode of the emission control transistor T6 may be connected to the emission control line EL, where one of a source region and a drain region of the emission control transistor T6 may be connected to the driving transistor T1 and the compensation transistor T3 via the third node N3, and the other of the source region and the drain region of the emission control transistor T6 may be electrically connected to the pixel electrode of the organic light-emitting diode OLED.

The operation control transistor T5 and the emission control transistor T6 may be simultaneously turned on in response to the emission control signal En received via the emission control line EL, so that the driving voltage ELVDD is applied to the organic light-emitting diode OLED and a driving current flows in the organic light-emitting diode OLED.

A second initialization gate electrode of the second initialization transistor T7 may be connected to the next scan line SLn, where one of a source region and a drain region of the second initialization transistor T7 may be connected to the pixel electrode of the organic light-emitting diode OLED, and the other of the source region and the drain region of the second initialization transistor T7 may be connected to the second initialization transistor T7 and receive the second initialization voltage Vint2. The second initialization transistor T7 may be turned on in response to the next scan signal Sn+1 received via the next scan line SLn, so that the pixel electrode of the organic light-emitting diode OLED is initialized. In an embodiment, the next scan line SLn and the first scan line SL1 may be a same line as each other. In such an embodiment, the corresponding scan line may be configured to transmit the same electrical signal with a time difference and may function as the first scan line SL1 and also as the next scan line SLn. In such an embodiment, the next scan line SLn may include a first scan line of a pixel, which is adjacent to the pixel P shown in FIG. 2, and electrically connected to the data line DL.

The second initialization transistor T7 may be connected to the first scan line SL1, as shown in FIG. 2. However, the disclosure is not limited thereto, and alternatively, the second initialization transistor T7 may be connected to the emission control line EL and driven according to the emission control signal En.

The storage capacitor Cst may include the first capacitor electrode CE1 and a second capacitor electrode CE2. The first capacitor electrode CE1 of the storage capacitor Cst may be connected to the driving gate electrode of the driving transistor T1 via the second node N2, and the second capacitor electrode CE2 of the storage capacitor Cst may be connected to the driving voltage line PL. The storage capacitor Cst may store a charge corresponding to a voltage difference between the driving gate electrode voltage of the driving transistor T1 and the driving voltage ELVDD.

A detailed operation of each pixel P according to an embodiment will hereinafter be described.

During an initialization period, when the previous scan signal Sn−1 is transmitted via the previous scan line SLp to the first initialization transistor T4, the first initialization transistor T4 may be turned on in response to the previous scan signal Sn−1, and the driving transistor T1 may be initialized according to the first initialization voltage Vint1 applied via the first initialization voltage line VL1.

During a data programming period, when the first scan signal Sn and the second scan signal Sn′ are respectively transmitted via the first scan line SL1 and the second scan line SL2, the switching transistor T2 and the compensation transistor T3 may be turned on in response to the first scan signal Sn and the second scan line Sn′. In this case, the driving transistor T1 may be diode-connected by the compensation transistor T3 that is turned on, and biased in a forward direction. Then, a compensation voltage (Dm+Vth, where Vth has a negative value), which is obtained by subtracting the data signal Dm received via the data line DL by a threshold voltage (Vth) of the driving transistor T1, may be applied to the driving gate electrode of the driving transistor T1. The driving voltage ELVDD and the compensation voltage (Dm+Vth) are respectively applied to opposite ends of the storage capacitor Cst, and a charge corresponding to a voltage difference between the opposite ends of the storage capacitor Cst may be stored in the storage capacitor Cst.

During an emission period, the operation control transistor T5 and the emission control transistor T6 may be turned on in response to the emission control signal En received via the emission control line EL. A driving current corresponding to a voltage difference between the voltage of the driving gate electrode of the driving transistor T1 and the driving voltage ELVDD may be generated, and the driving current may be supplied to the organic light-emitting diode OLED via the emission control transistor T6.

As described above, some of the plurality of thin-film transistors T1 to T7 may include an oxide semiconductor. In an embodiment, for example, the compensation transistor T3 and the first initialization transistor T4 may include an oxide semiconductor.

In a case of a transistor including polysilicon, which is highly reliable, the transistor may be precisely controlled so that an intended current flows. Accordingly, in an embodiment where a semiconductor layer including highly-reliable polysilicon is included in the driving transistor T1 that directly affects a brightness of the display apparatus, a high-resolution display apparatus may be implemented. In addition, an oxide semiconductor has high carrier mobility and low leakage current, and thus, a voltage drop is not large even when a driving time is long. In other words, in an oxide semiconductor, a change in color of an image according to a voltage drop is not large even when the display apparatus is driven at low frequencies, and thus, the display apparatus may be driven at low frequencies. Accordingly, in an embodiment, the compensation transistor T3 and the first initialization transistor T4 include an oxide semiconductor, such that a display apparatus with reduced power consumption while preventing leakage current may be implemented.

Such an oxide semiconductor may be sensitive to light, and thus, an amount of current or the like may vary depending on external light. Accordingly, a metal layer may be disposed under the oxide semiconductor and absorb or reflect the external light. Accordingly, in an embodiment shown in FIG. 2, in each of the compensation transistor T3 and the first initialization transistor T4 including the oxide semiconductor, a gate electrode may be over and under an oxide semiconductor layer. In such an embodiment, when viewed from the direction perpendicular to the upper surface of the substrate 100 (the z-axis direction), the metal layer disposed under the oxide semiconductor may overlap the oxide semiconductor.

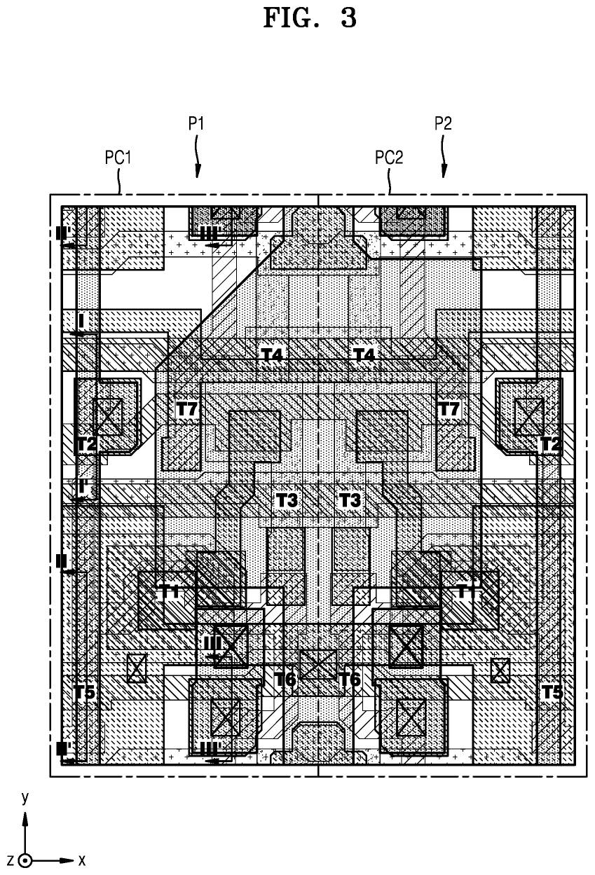

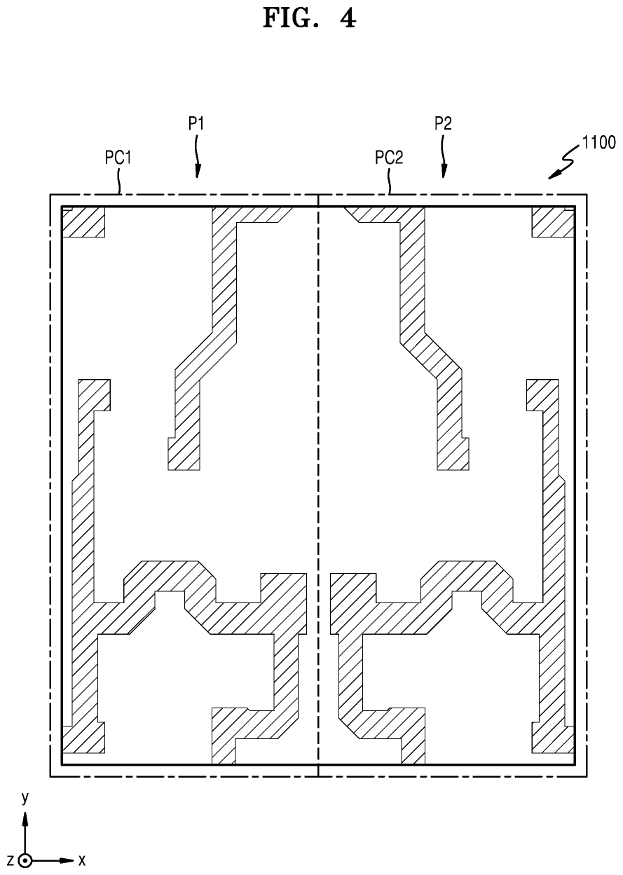

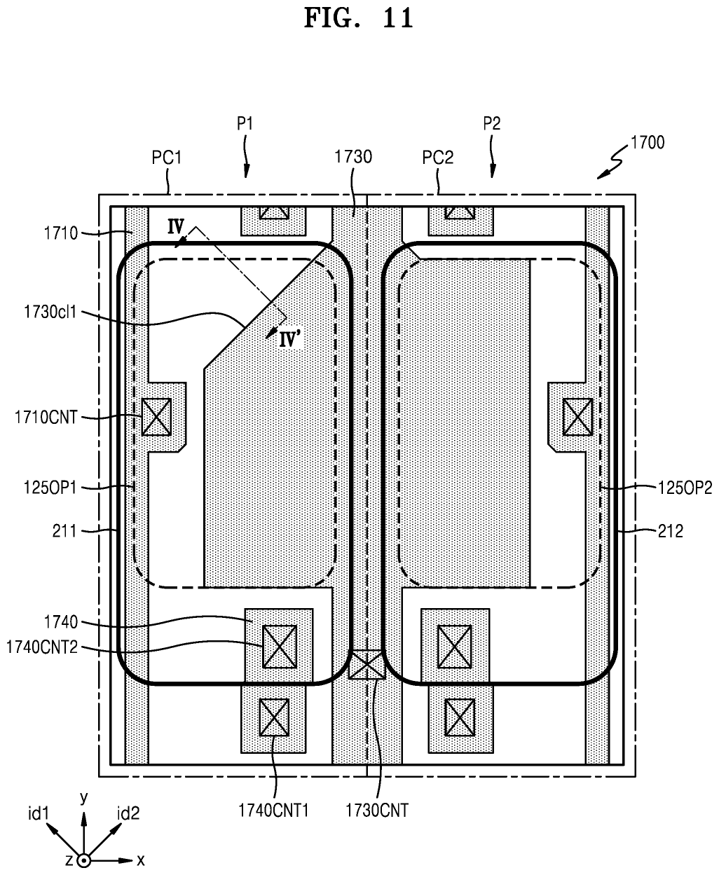

FIG. 3 is a plan view schematically illustrating positions of the thin-film transistors T1 to T7, the storage capacitor Cst, or the like in pixels included in the display apparatus in FIG. 1, FIGS. 4 to 10 are plan views schematically illustrating elements of the display apparatus shown in FIG. 3, such as the thin-film transistors T1 to T7 and the storage capacitor Cst, for each layer, FIG. 11 is a plan view schematically illustrating a first pixel electrode 211 and a second pixel electrode 212 together on the layer in FIG. 10, and FIG. 12 is a cross-sectional view schematically illustrating cross-sections of the display apparatus shown in FIG. 3, taken along lines I-I′, II-II′, and III-III′.

As shown in FIGS. 3 to 12, the display apparatus may include a first pixel P1 and a second pixel P2 that are adjacent to each other. The first pixel P1 and the second pixel P2 may be approximately symmetrical to each other with respect to an imaginary bound line, as shown in FIG. 3, etc. However, the disclosure is not limited thereto, and the first pixel P1 and the second pixel P2 may be configured in various different ways.

The first pixel P1 may include a first pixel circuit PC1, and the second pixel P2 may include a second pixel circuit PC2. Hereinafter, for convenience of description, some conductive patterns are described based on the first pixel circuit PC1, but these conductive patterns may also be arranged approximately symmetrically in the second pixel circuit PC2.

A buffer layer 111, as shown in FIG. 12, may be disposed on the substrate 100, where the buffer layer 111 includes silicon oxide, silicon nitride, or silicon oxynitride. The buffer layer 111 may prevent a phenomenon in which metal atoms or impurities from the substrate 100 diffuse to a first semiconductor layer 1100 disposed over the substrate 100. In addition, during a crystallization process of forming the first semiconductor layer 1100, the buffer layer 111 may adjust a rate at which heat is provided, so that the first semiconductor layer 1100 is uniformly crystallized.

The first semiconductor layer 1100, as shown in FIGS. 4 and 12, may be disposed on the buffer layer 111. The first semiconductor layer 1100 may include a silicon semiconductor. In an embodiment, for example, the first semiconductor layer 1100 may include amorphous silicon or polysilicon. In an embodiment, for example, the first semiconductor layer 1100 may include polysilicon crystallized at a low temperature. In some embodiments, ions may be injected into at least a portion of the first semiconductor layer 1100.

In such an embodiment, the driving transistor T1, the switching transistor T2, the operation control transistor T5, the emission control transistor T6, and the second initialization transistor T7 may be PMOS, as described above, and these thin-film transistors may be positioned along the first semiconductor layer 1100, as shown in FIG. 4. In addition, the first semiconductor layer 1100 may have a shape extending in a first direction (a +y direction) as a whole.

A first gate insulation layer 113, as shown in FIG. 12, may be disposed over the substrate 100 and cover the first semiconductor layer 1100. The first gate insulation layer 113 may include an insulating material. In an embodiment, for example, the first gate insulation layer 113 may include an inorganic insulation layer, such as a silicon oxide layer, a silicon nitride layer, a silicon oxynitride layer, an aluminum oxide layer, or the like.

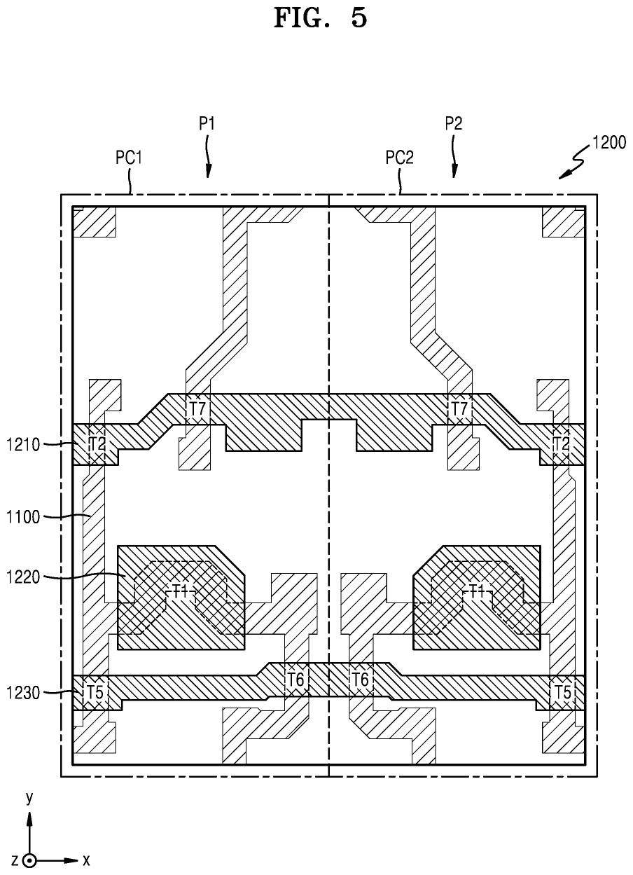

A first conductive layer 1200, as shown in FIGS. 5 and 12, may be disposed on the first gate insulation layer 113. In FIG. 5, the first semiconductor layer 1100 is shown together with the first conductive layer 1200, for convenience of illustration and description. The first conductive layer 1200 may include a first gate line 1210, a first gate electrode 1220, and a second gate line 1230. The first conductive layer 1200 as described above may also be referred to as a first gate layer.

The first gate line 1210 may extend in a second direction (a +x direction). The first gate line 1210 may include the first scan line SL1 or the next scan line SLn in FIG. 2. In such an embodiment, in the first pixel P1 shown in FIG. 5, the first gate line 1210 may correspond to the first scan line SL1 in FIG. 2, and in a pixel arranged adjacent to the first pixel P1 in the first direction (the +y direction), the first gate line 1210 may correspond to the next scan line SLn in FIG. 2. Accordingly, the first scan signal Sn and the next scan signal Sn+1 may be transmitted to the pixels via the first gate line 1210. Portions of the first gate line 1210 overlapping the first semiconductor layer 1100 may include the switching gate electrode of the switching transistor T2 and the second initialization gate electrode of the second initialization transistor T7.

The first gate electrode 1220 may have an isolated shape. The first gate electrode 1220 may include the driving gate electrode of the driving transistor T1. For reference, a portion of the first semiconductor layer 1100 overlapping the first gate electrode 1220 and a portion therearound may be referred to as a driving semiconductor layer.

The second gate line 1230 may extend in the second direction (the +x direction). The second gate line 1230 may correspond to the emission control line EL in FIG. 2. Portions of the second gate line 1230 overlapping the first semiconductor layer 1100 may include the operation control gate electrode of the operation control transistor T5 and the emission control gate electrode of the emission control transistor T6. The emission control signal En may be transmitted to the pixels via the second gate line 1230.

The first conductive layer 1200 may include a metal, an alloy, a conductive metal oxide, a transparent conductive material, or the like. In an embodiment, for example, the first conductive layer 1200 may include silver (Ag), an Ag-containing alloy, molybdenum (Mo), a Mo-containing alloy, aluminum (Al), an Al-containing alloy, an aluminum nitride (AlN), tungsten (W), a tungsten nitride (WN), copper (Cu), nickel (Ni), chrome (Cr), a chrome nitride (CrN), titanium (Ti), tantalum (Ta), platinum (Pt), scandium (Sc), an indium tin oxide (ITO), an indium zinc oxide (IZO), or the like. The first conductive layer 1200 may have a multi-layer structure, such as a two-layer structure of a Mo layer and an Al layer, or a three-layer structure of a Mo layer, an Al layer, and another Mo layer, for example.

A second gate insulation layer 115, as shown in FIG. 12, may be disposed on the first gate insulation layer 113 and cover the first conductive layer 1200. The second gate insulation layer 115 may include the same/similar insulating material as/to the first gate insulation layer 113.

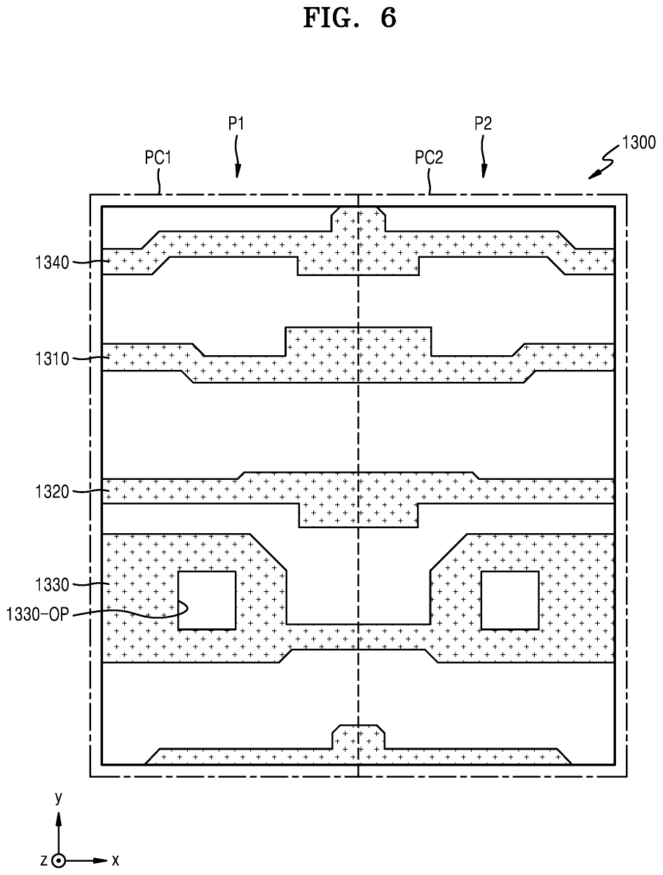

A second conductive layer 1300, as shown in FIGS. 6 and 12, may be disposed on the second gate insulation layer 115. The second conductive layer 1300 may include a third gate line 1310, a fourth gate line 1320, a capacitor upper electrode 1330, and a first initialization voltage line 1340 (i.e., the first initialization voltage line VL1 in FIG. 2).

The third gate line 1310 may extend in the second direction (the +x direction). The third gate line 1310 may correspond to the previous scan line SLp in FIG. 2. When viewed from the direction perpendicular to the substrate 100 (the z-axis direction), the third gate line 1310 may be apart from the first gate line 1210. The previous scan signal Sn−1 may be transmitted to the pixels via the third gate line 1310. A portion of the third gate line 1310 overlapping a second semiconductor layer 1400 to be described later may include a first initialization lower gate electrode of the first initialization transistor T4.

The fourth gate line 1320 may also extend in the second direction (the +x direction). The fourth gate line 1320 may correspond to the second scan line SL2 in FIG. 2. When viewed from the direction perpendicular to the substrate 100 (the z-axis direction), the fourth gate line 1320 may be apart from the first gate line 1210 and the third gate line 1310. The second scan signal Sn′ may be transmitted to the pixels via the fourth gate line 1320. A portion of the fourth gate line 1320 overlapping the second semiconductor layer 1400 to be described later may include a compensation lower gate electrode of the compensation transistor T3.

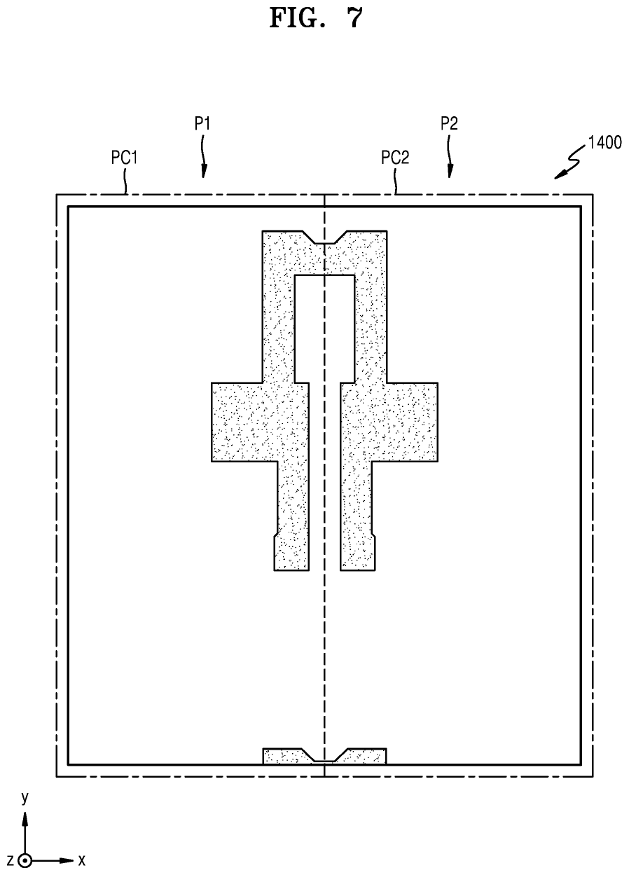

The third gate line 1310 and the fourth gate line 1320 may be disposed under the second semiconductor layer 1400 to be described later with reference to FIG. 7, to function as gate electrodes and also as lower protective metals for protecting portions of the second semiconductor layer 1400 overlapping the third gate line 1310 and the fourth gate line 1320.

The capacitor upper electrode 1330 may overlap the first gate electrode 1220 and extend in the second direction (the +x direction). The capacitor upper electrode 1330 described above may constitute the second capacitor electrode CE2 together with the first gate electrode 1220, to correspond to the second capacitor electrode CE2 in FIG. 2. The driving voltage ELVDD may be applied to the capacitor upper electrode 1330. In addition, a hole passing through the capacitor upper electrode 1330 may be defined in the capacitor upper electrode 1330, and at least a portion of the first gate electrode 1220 may overlap the hole.

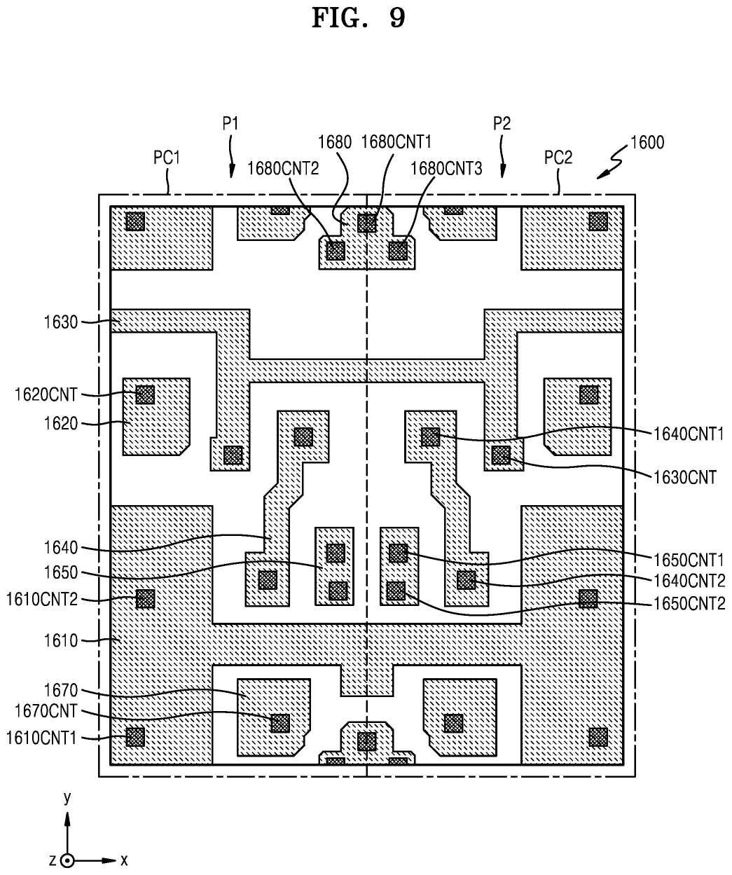

The first initialization voltage line 1340 corresponding to the first initialization voltage line VL1 in FIG. 2 may extend in the second direction (the +x direction). When viewed from the direction perpendicular to the substrate 100 (the z-axis direction), the first initialization voltage line 1340 may be apart from the third gate line 1310. The first initialization voltage Vint1 may be applied to the pixels via the first initialization voltage line 1340. The first initialization voltage line 1340 may at least partially overlap the second semiconductor layer 1400 to be described later and may be configured to apply the first initialization voltage line 1340 to the second semiconductor layer 1400. The first initialization voltage line 1340 may be electrically connected to the second semiconductor layer 1400 via contact holes 1680CNT1, 1680CNT2, and 1680CNT3 to be described later with reference to FIG. 9.

The second conductive layer 1300 may include a metal, an alloy, a conductive metal oxide, a transparent conductive material, or the like. In an embodiment, for example, the second conductive layer 1300 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, or IZO. The second conductive layer 1300 may have a multi-layer structure, such as a two-layer structure of a Mo layer and an Al layer, or a three-layer structure of a Mo layer, an Al layer, and another Mo layer, for example.

A first interlayer insulation layer 117, as shown in FIG. 12, may be disposed on the second gate insulation layer 115 and cover the second conductive layer 1300. The first interlayer insulation layer 117 may include an insulating material. In an embodiment, for example, the first interlayer insulation layer 117 may include silicon oxide, silicon nitride, silicon oxynitride, aluminum oxide, or the like.

The second semiconductor layer 1400, as shown in FIGS. 7 and 12, may be disposed on the first interlayer insulation layer 117. As described above, the second semiconductor layer 1400 may include an oxide semiconductor. The second semiconductor layer 1400 may be disposed in a layer different from a layer in which the first semiconductor layer 1100 is disposed, and may not overlap the first semiconductor layer 1100, when viewed from the direction perpendicular to the substrate 100 (the z-axis direction).

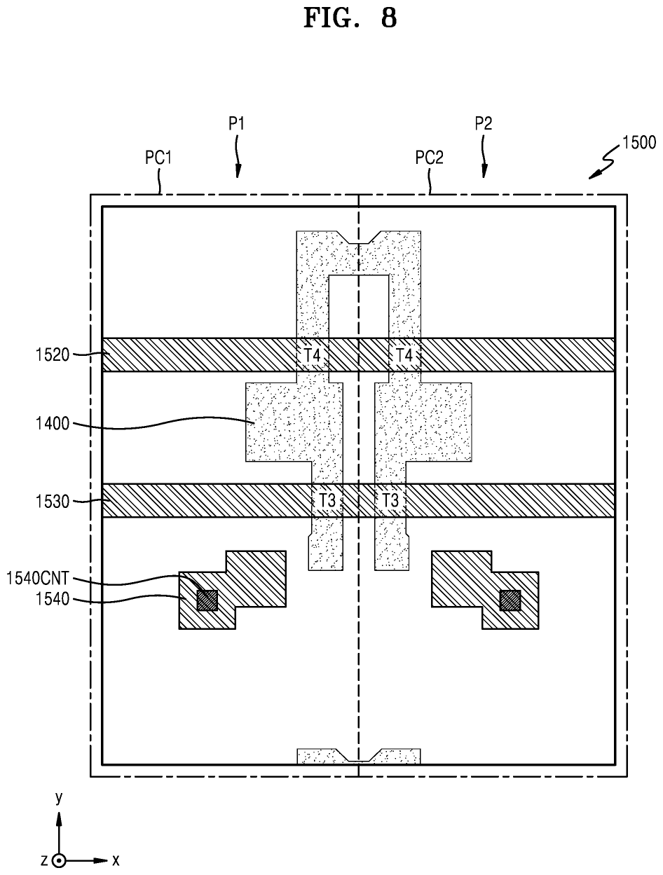

A third gate insulation layer 118, as shown in FIG. 12, may be disposed on the first interlayer insulation layer 117 and cover the second semiconductor layer 1400. The third gate insulation layer 118 may include an insulating material. In an embodiment, the third gate insulation layer 118 may be disposed only on a portion of the second semiconductor layer 1400 and not on the first interlayer insulation layer 117. In such an embodiment, the third gate insulation layer 118 may have the same pattern as a third gate layer 1500 to be described later with reference to FIG. 8. In an embodiment, when viewed from the direction perpendicular to the substrate 100 (the z-axis direction), the third gate insulation layer 118 may completely or almost completely overlap the third gate layer 1500. In such an embodiment, the third gate insulation layer 118 and the third gate layer 1500 may be simultaneously patterned with each other. Accordingly, in the second semiconductor layer 1400, source regions and drain regions may not be covered with the third gate insulation layer 118 except for channel areas overlapping the third gate layer 1500. The source regions and the drain regions may be in direct contact with a second interlayer insulation layer 119. The third gate insulation layer 118 may include silicon oxide, silicon nitride, silicon oxynitride, aluminum oxide, or the like.

The third gate layer 1500, as shown in FIGS. 8 and 12, may be disposed on the third gate insulation layer 118. The third gate layer 1500 may include a fifth gate line 1520, a sixth gate line 1530, and an intermediate electrode 1540.

The fifth gate line 1520 may extend in the second direction (the +x direction). When viewed from the direction perpendicular to the substrate 100 (the z-axis direction), the fifth gate line 1520 may overlap the third gate line 1310. A portion of the fifth gate line 1520 overlapping the second semiconductor layer 1400 may include a first initialization upper gate electrode of the first initialization transistor T4. A portion of the second semiconductor layer 1400 overlapping the fifth gate line 1520 and a portion therearound may be referred to as a first initialization semiconductor layer. The fifth gate line 1520 may be electrically connected to the third gate line 1310. In an embodiment, for example, the fifth gate line 1520 may be electrically connected to the third gate line 1310 via a contact hole defined in an insulation layer between the fifth gate line 1520 and the third gate line 1310. The contact hole may be in the display area DA or in the peripheral area PA. Accordingly, the fifth gate line 1520 may correspond to the previous scan line SLp in FIG. 2 together with the third gate line 1310. Accordingly, the previous scan signal Sn−1 may be transmitted to the pixels via the fifth gate line 1520 and/or the third gate line 1310.

The sixth gate line 1530 may extend in the second direction (the +x direction). When viewed from the direction perpendicular to the substrate 100 (the z-axis direction), the sixth gate line 1530 may overlap the fourth gate line 1320. A portion of the sixth gate line 1530 overlapping the second semiconductor layer 1400 may include a compensation upper gate electrode of the compensation transistor T3. The sixth gate line 1530 may be electrically connected to the fourth gate line 1320. In an embodiment, for example, the sixth gate line 1530 may be electrically connected to the fourth gate line 1320 via a contact hole defined in an insulation layer between the sixth gate line 1530 and the fourth gate line 1320. The contact hole may be in the display area DA or the peripheral area PA. Accordingly, the sixth gate line 1530 may correspond to the second scan line SL2 in FIG. 2 together with the fourth gate line 1320. Accordingly, the second scan signal Sn′ may be transmitted to the pixels via the sixth gate line 1530 and/or the fourth gate line 1320.

The intermediate electrode 1540 may be electrically connected to the first gate electrode 1220, which is a driving gate electrode, through a contact hole 1540CNT defined to overlap an opening 1330-OP of the capacitor upper electrode 1330. The intermediate electrode 1540 may apply the first initialization voltage Vint1 received via the first initialization transistor T4 to the first gate electrode 1220.

The third gate layer 1500 may include a metal, an alloy, a conductive metal oxide, a transparent conductive material, or the like. In an embodiment, for example, the third gate layer 1500 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, IZO, or the like. The third gate layer 1500 may have a multi-layer structure, such as a two-layer structure of a Mo layer and an Al layer, or a three-layer structure of a Mo layer, an Al layer, and another Mo layer, for example.

The second interlayer insulation layer 119, as shown in FIG. 12, may cover at least a portion of the third gate layer 1500 in FIG. 8. The second interlayer insulation layer 119 may include an insulating material. In an embodiment, for example, the second interlayer insulation layer 119 may include silicon oxide, silicon nitride, silicon oxynitride, aluminum oxide, or the like.

A first connection electrode layer 1600, as shown in FIGS. 9 and 12, may be disposed on the second interlayer insulation layer 119. The first connection electrode layer 1600 may include a first connection electrode 1620, a second connection electrode 1610, a second initialization voltage line 1630, a third connection electrode 1670, a fourth connection electrode 1640, a fifth connection electrode 1650, and a sixth connection electrode 1680.

The first connection electrode 1620 may be electrically connected to the first semiconductor layer 1100 via a contact hole 1620CNT. The data signal Dm from a data line 1710 to be described later with reference to FIG. 10 may be transmitted to the first semiconductor layer 1100 via the first connection electrode 1620 such that the data signal Dm is transmitted to the switching transistor T2.

The second initialization voltage line 1630 may extend in the second direction (the +x direction). The second initialization voltage line 1630, which corresponds to the second initialization voltage line VL2 in FIG. 2, may be configured to apply the second initialization voltage Vint2 to the pixels. The second initialization voltage line 1630 may be electrically connected to the first semiconductor layer 1100 via a contact hole 1630CNT so that the second initialization voltage Vint2 may be applied to the first semiconductor layer 1100 and the second initialization transistor T7.

The driving voltage ELVDD from a driving power supply line 1730 to be described later with reference to FIG. 10 may be transferred to the second connection electrode 1610. The second connection electrode 1610, which is electrically connected to the first semiconductor layer 1100 via a contact hole 1610CNT1, may apply the driving voltage ELVDD to the first semiconductor layer 1100, for example, the operation control transistor T5. In addition, the second connection electrode 1610 electrically connected to the capacitor upper electrode 1330 (i.e., the second capacitor electrode CE2 in FIG. 2) via a contact hole 1610CNT2, which may be referred to as an additional contact hole, may apply the driving voltage ELVDD to the capacitor upper electrode 1330.

In an embodiment, the second connection electrode 1610 may extend in the second direction (the +x direction). Accordingly, the second connection electrode 1610 may constitute a mesh structure together with the driving power supply line 1730 extending in the first direction (the +y direction), which is described later with reference to FIG. 10. However, the disclosure is not limited thereto, and the second connection electrode 1610 may also have an isolated shape.

The third connection electrode 1670 may be electrically connected to the first semiconductor layer 1100 via a contact hole 1670CNT. The third connection electrode 1670 may transfer a driving current or a second initialization voltage Vint2 from the first semiconductor layer 1100 to the organic light-emitting diode OLED.

The fourth connection electrode 1640 may electrically connect the second semiconductor layer 1400 and the intermediate electrode 1540 to each other via contact holes 1640CNT1 and 1640CNT2 defined at one side and the other side of the fourth connection electrode 1640. The intermediate electrode 1540 may be electrically connected to the first gate electrode 1220 that is a driving gate electrode, and as a result, the fourth connection electrode 1640 may electrically connect the first initialization semiconductor, which is a portion of the second semiconductor layer 1400, to the driving gate electrode. The first initialization voltage Vint1 may be applied to the first gate electrode 1220 that is a driving gate electrode through the second semiconductor layer 1400, the fourth connection electrode 1640, and the intermediate electrode 1540.

The fifth connection electrode 1650 may electrically connect the second semiconductor layer 1400 and the first semiconductor layer 1100 to each other via contact holes 1650CNT1 and 1650CNT2 defined at one side and the other side of the fifth connection electrode 1650. In such an embodiment, the fifth connection electrode 1650 may electrically connect the compensation transistor T3 and the driving transistor T1 to each other.

The sixth connection electrode 1680 may be electrically connected to the second semiconductor layer 1400 via contact holes 1680CNT2 and 1680CNT3. In addition, the sixth connection electrode 1680 may be electrically connected to the first initialization voltage line 1340 in FIG. 6 via a contact hole 1680CNT1. Accordingly, the sixth connection electrode 1680 may transfer the first initialization voltage Vint1 from the first initialization voltage line 1340 to the first initialization transistor T4.

The first connection electrode layer 1600 may include a metal, an alloy, a conductive metal oxide, a transparent conductive material, or the like. In an embodiment, for example, the first connection electrode layer 1600 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, IZO, or the like. The first connection electrode layer 1600 may have a multi-layer structure, such as a two-layer structure of a Ti layer and an Al layer, or a three-layer structure of a Ti layer, an Al layer, and another Ti layer, for example.

A first planarization layer 121, as shown in FIG. 12, may be disposed on the second interlayer insulation layer 119 and cover the first connection electrode layer 1600. The first planarization layer 121 may include an organic insulating material. In an embodiment, for example, the first planarization layer 121 may include photoresist, benzocyclobutene (BCB), polyimide, hexamethyldisiloxane (HMDSO), polymethylmethacrylate (PMMA), polystyrene, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or any blends thereof.

A second connection electrode layer 1700, as shown in FIGS. 10 and 12, may be disposed on the first planarization layer 121. The second connection electrode layer 1700 may include the data line 1710, the driving power supply line 1730, and an upper connection electrode 1740.

The data line 1710 may extend in the first direction (the +y direction). The data line 1710 may correspond to the data line DL in FIG. 2. The data line 1710 may be electrically connected to the first connection electrode 1620 via a contact hole 1710CNT so that the data signal Dm from the data line 1710 may be transmitted to the first semiconductor layer 1100 via the first connection electrode 1620 and transmitted to the switching transistor T2.

The driving power supply line 1730 may extend in approximately the first direction (the +y direction). The driving power supply line 1730 may correspond to the driving voltage line PL in FIG. 2. The driving power supply line 1730 may be configured to apply the driving voltage ELVDD to the pixels. The driving power supply line 1730 may be electrically connected to the second connection electrode 1610 via a contact hole 1730CNT so that the driving voltage ELVDD may be applied to the operation control transistor T5 and the capacitor upper electrode 1330, as described above. The driving power supply line 1730 of the first pixel circuit PC1 may be integrally formed as a single unitary and indivisible body with the driving power supply line 1730 of the second pixel circuit PC2 adjacent to the first pixel circuit PC1.

When viewed from the direction perpendicular to the substrate 100 (the z-axis direction), the driving power supply line 1730 may have a protrusion (or an expanded portion) in the second direction (the +x direction) or a direction (the −x direction) opposite thereto, while extending in approximately the first direction (the +y direction). In an embodiment, as shown in FIG. 11, in the first pixel P1, the driving power supply line 1730 has a first protrusion in a direction (the −x direction) opposite to the second direction, and in the second pixel P2, the driving power supply line 1730 has a second protrusion in the second direction (the +x direction). When viewed from the direction perpendicular to the substrate 100 (the z-axis direction), the second protrusion approximately has a rectangular shape, while the first protrusion has a shape of which a portion is chamfered. In such an embodiment, the first protrusion has a shape in which an end edge in a first inclined direction (a +Id1 direction), which is a direction between the first direction (the +y direction) and a direction (the −x direction) opposite to the second direction, is chamfered. Accordingly, the first protrusion may have a first chamfer line 1730cl1 extending in a second inclined direction (a +Id2 direction), which is approximately perpendicular to the first inclined direction (the +Id1 direction), and is a direction between the first direction (the +y direction) and the second direction (the +x direction).

The upper connection electrode 1740 may be electrically connected to the third connection electrode 1670 via a contact hole 1740CNT1. In addition, the upper connection electrode 1740 may be connected to a first pixel electrode 211 thereon, through a contact hole 1740CNT2 defined in an insulation layer disposed on the upper connection electrode 1740. Accordingly, a driving current or the second initialization voltage Vint2 from the first semiconductor layer 1100 may be transferred to the pixel electrode of the organic light-emitting diode OLED via the third connection electrode 1670 and the upper connection electrode 1740.

The second connection electrode layer 1700 may include a metal, an alloy, a conductive metal oxide, a transparent conductive material, or the like. In an embodiment, for example, the second connection electrode layer 1700 may include Ag, an Ag-containing alloy, Mo, a Mo-containing alloy, Al, an Al-containing alloy, AlN, W, WN, Cu, Ni, Cr, CrN, Ti, Ta, Pt, Sc, ITO, IZO, or the like. The second connection electrode layer 1700 may have a multi-layer structure, such as a two-layer structure of a Ti layer and an Al layer, or a three-layer structure of a Ti layer, an Al layer, and another Ti layer, for example.

A second planarization layer 123, as shown in FIG. 12, may be disposed on the first planarization layer 121 and cover the second connection electrode layer 1700. The second planarization layer 123 may include an organic insulating material. In an embodiment, for example, the second planarization layer 123 may include photoresist, BCB, polyimide, HMDSO, PMMA, polystyrene, a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, or any blends thereof.

An organic light-emitting diode may be disposed on the second planarization layer 123. The organic light-emitting diode may include a pixel electrode, an intermediate layer, and an opposite electrode, where the intermediate layer includes an emission layer. In an embodiment, as shown in FIG. 11, the first pixel electrode 211 is in the first pixel P1, and a second pixel electrode 212 is in the second pixel P2. In an embodiment, as shown in FIG. 12, an organic light-emitting diode OLED1 is in the first pixel P1, and the organic light-emitting diode OLED1 includes an intermediate layer 221 and an opposite electrode 230, where the intermediate layer 221 includes an emission layer.

The first pixel electrode 211 and the second pixel electrode 212 may include a (semi-)light-transmitting electrode or a reflective electrode. In an embodiment, for example, the first pixel electrode 211 and the second pixel electrode 212 may include a reflective layer and a transparent or semi-transparent electrode layer disposed on the reflective layer, where the reflective layer includes Ag, magnesium (Mg), Al, Pt, palladium (Pd), gold (Au), Ni, neodymium (Nd), iridium (Ir), Cr, and a compound thereof. The transparent or semi-transparent electrode layer may include at least one selected from ITO, IZO, zinc oxide (ZnO), indium oxide (In₂O₃), indium gallium oxide (IGO), and aluminum zinc oxide (AZO). In an embodiment, for example, the first pixel electrode 211 and the second pixel electrode 212 may have a three-layer structure of an ITO layer, an Ag layer, and another ITO layer.

A pixel-defining layer 125, as shown in FIG. 12, may be disposed on the second planarization layer 123. The pixel-defining layer 125 may prevent an arc or the like from occurring at the edges of the first pixel electrode 211 and the second pixel electrode 212 by increasing a distance between an edge of each of the first pixel electrode 211 and the second pixel electrode 212 and the opposite electrode 230 over the first pixel electrode 211 and the second pixel electrode 212. In such an embodiment, the pixel-defining layer 125 may have a first opening 1250P1 and expose a central portion of the first pixel electrode 211 of the first pixel P1, and the pixel-defining layer 125 may have a second opening 125OP2 and expose a central portion of the second pixel electrode 212 of the second pixel P2. The pixel-defining layer 125 may include one or more organic insulating materials selected from polyimide, polyamide, an acryl-based resin, BCB, and a phenolic resin, and may be provided by a method such as spin coating.

At least a portion of the intermediate layer 221 of the organic light-emitting diode OLED1, which includes an emission layer, may be in the first opening 1250P1 defined by the pixel-defining layer 125. By the first opening 1250P1, an emission area of the organic light-emitting diode OLED1 may be defined. Similarly, in the second pixel P2, at least a portion of an intermediate layer (not shown) including an emission layer may be in the second opening 125OP2 defined by the pixel-defining layer 125. The emission layer included in the intermediate layer of the second pixel P2 may emit light of a wavelength different from a wavelength of the emission layer included in the intermediate layer 221 of the first pixel P1.

As described above, an intermediate layer may include an emission layer. The emission layer may include an organic material including a fluorescent or phosphorous material emitting red, green, blue, or white light. The emission layer may include a low-molecular weight organic material or a polymer organic material, and under and over the emission layer, a functional layer, such as a hole transport layer (HTL), a hole injection layer (HIL), an electron transport layer (ETL), and an electron injection layer (EIL), may selectively be further disposed.

The emission layer may have a patterned shape to correspond to each of the first pixel electrode 211 and the second pixel electrode 212. Layers included in the intermediate layer except for the emission layer may be integrally formed as a single unitary and indivisible body over the first pixel electrode 211 and the second pixel electrode 212, and various modifications may be made.

The opposite electrode 230 may include a light-transmitting electrode or a reflective electrode. In an embodiment, for example, the opposite electrode 230 may include a transparent or semi-transparent electrode, and may include a metal thin film having a low work function that includes lithium (Li), calcium (Ca), lithium fluoride (LiF), Al, Ag, Mg, and a compound thereof. In addition, the opposite electrode 230 may further include a transparent conductive oxide (TCO) layer, which may include ITO, IZO, ZnOₓ (ZnO or ZnO₂), or In₂O₃. The opposite electrode 230 may be integrally formed as a single unitary and indivisible body over the entire surface of the display area DA, and may be disposed over the intermediate layer and the pixel-defining layer 125.

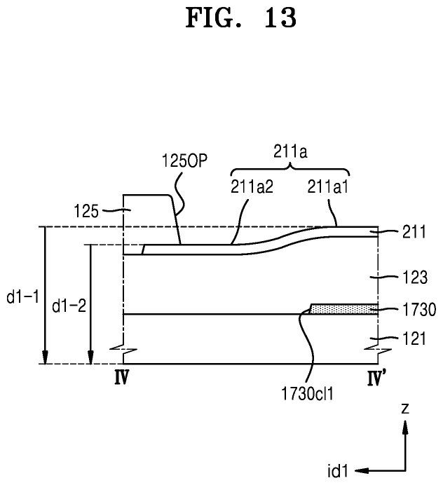

FIG. 13 is a cross-sectional view schematically illustrating a cross-section of the display apparatus shown in FIG. 11, taken along line IV-IV′. In an embodiment, as described above, when viewed from the direction perpendicular to the substrate 100 (the z-axis direction), the first protrusion positioned in the first pixel P1 may have a shape of which a portion is chamfered. In such an embodiment, the first protrusion may have a shape in which an end edge in the first inclined direction (the +Id1 direction) is chamfered, and have the first chamfer line 1730cl1 extending in the second inclined direction (the +Id2 direction). Accordingly, as shown in FIG. 13, the second planarization layer 123 may have a gently (or gradually) inclined upper surface in an area adjacent to the first chamfer line 1730cl1 of the driving power supply line 1730. In addition, the first pixel electrode 211 in the first pixel P1 may have an inclined shape along a shape of the upper surface of the second planarization layer 123. Accordingly, an upper surface 211a of the first pixel electrode 211 positioned in the first pixel P1 (hereinafter, “first upper surface”) may have an inclined surface with respect to the upper surface of the substrate 100 between a first portion 211a1 (hereinafter, will be referred to as “1^{st}-1^{st} portion”) and a second portion 211a2 (hereinafter, will be referred to as “1^{st}-2^{nd} portion”).

In such an embodiment, the first upper surface 211a of the first pixel electrode 211 may have the 1^{st}-1^{st} portion 211a1 and the 1^{st}-2^{nd} portion 211a2, where the 1^{st}-1^{st} portion 211a1 corresponds to (e.g., overlapping in the z-axis direction) the protrusion of the driving power supply line 1730, and the 1^{st}-2^{nd} portion 211a2 does not correspond to the protrusion of the driving power supply line 1730. This may be understood that, when viewed from the direction perpendicular to the substrate 100 (the z-axis direction), the protrusion of the driving power supply line 1730 corresponds to the 1^{st}-1^{st} portion 211a1 of the first upper surface 211a of the first pixel electrode 211, that is, the protrusion of the driving power supply line 1730 overlaps the 1^{st}-1^{st} portion 211a1 of the first upper surface 211a of the first pixel electrode 211. In addition, the protrusion of the driving power supply line 1730 may not overlap the 1^{st}-2^{nd} portion 211a2 of the first upper surface 211a of the first pixel electrode 211. Accordingly, a distance d1-1 from the 1^{st}-1^{st} portion 211a1 of the first upper surface 211a of the first pixel electrode 211 to the upper surface of the substrate 100 (hereinafter, will be referred to as “1^{st}-1^{st} distance”) may be greater than a distance d1-2 from the 1^{st}-2^{nd} portion 211a2 of the first upper surface 211a to the upper surface of the substrate 100 (hereinafter, will be referred to as“1^{st}-2^{nd} distance”). In addition, the first upper surface 211a of the first pixel electrode 211 may have an inclined shape with respect to the substrate 100 between a center of the 1^{st}-1^{st} portion 211a1 and a center of the 1^{st}-2^{nd} portion 211a2.

When viewed from the direction perpendicular to the substrate 100 (the z-axis direction), the driving power supply line 1730 may have the first chamfer line 1730cl1 extending in a direction crossing a line connecting the central portion of the 1^{st}-1^{st} portion 211a1 and the central portion of the 1^{st}-2^{nd} portion 211a2. Accordingly, in the first upper surface 211a of the first pixel electrode 211, an imaginary boundary between the 1^{st}-1^{st} portion 211a1 and the 1^{st}-2^{nd} portion 211a2 may correspond to the first chamfer line 1730cl1 of the first protrusion extending in the second inclined direction (the +Id2 direction). In addition, the line connecting the central portion of the 1^{st}-1^{st} portion 211a1 of the first pixel electrode 211 and the central portion of the 1^{st}-2^{nd} portion 211a2 of the first pixel electrode 211 may extend in the first inclined direction (the +Id1 direction) crossing the first chamfer line 1730cl1. In FIG. 11, the line connecting the central portion of the 1^{st}-1^{st} portion 211a1 of the first pixel electrode 211 and the central portion of the 1^{st}-2^{nd} portion 211a2 of the first pixel electrode 211 extends in the first inclined direction (the +Id1 direction) perpendicular to the first chamfer line 1730cl1.

In such an embodiment, as shown in FIG. 11, the line connecting the central portion of the 1^{st}-1^{st} portion 211a1 of the first pixel electrode 211 and the central portion of the 1 st-2^{nd} portion 211a2 of the first pixel electrode 211 may form an acute angle with the first direction (the +y direction), in which the data line 1710 extends. In an embodiment, for example, as shown in FIG. 11, the line connecting the central portion of the 1^{st}-1 St portion 211a1 of the first pixel electrode 211 and the central portion of the 1^{st}-2^{nd} portion 211a2 of the first pixel electrode 211 may form about 45 degrees with the first direction (the +y direction), in which the data line 1710 extends. In such an embodiment, when viewed from the direction perpendicular to the substrate 100 (the z-axis direction), the central portion of the 1^{st}-2^{nd} portion 211a2 may be positioned closer to the data line 1710 than the central portion of the 1^{st}-1^{st} portion 211a1, and the central portion of the 1^{st}-2^{nd} portion 211a2 may be positioned in the first direction (the +y direction) from the central portion of the 1^{st}-1^{st} portion 211a1.

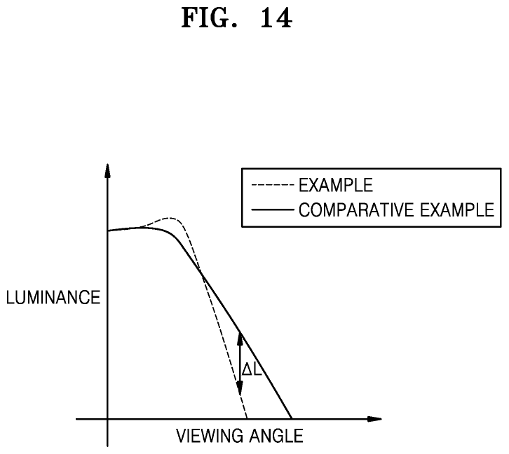

FIG. 14 is a graph schematically illustrating a change in luminance according to a change in viewing angle in the display apparatus shown in FIG. 13 and in a display apparatus according to a comparative example. In the graph of FIG. 14, the horizontal axis indicates a viewing angle, and the vertical axis indicates luminance. The viewing angle defines an angle in the direction perpendicular to the substrate 100 (the z-axis direction) to 0 degrees, and denotes an angle between the direction perpendicular to the substrate 100 (the z-axis direction) and a viewing direction. In the graph of FIG. 14, the solid line indicates a change in luminance according to a change in viewing angle in a display apparatus according to a comparative example (COMPARATIVE EXAMPLE) where the upper surface of a pixel electrode is approximately flat, and the dotted lines indicate a change in luminance according to a change in viewing angle in a display apparatus according to an embodiment shown in FIG. 13 (EXAMPLE) where the upper surface of the pixel electrode is inclined. In this case, with the direction perpendicular to the upper surface of the substrate 100 (the z-axis direction) being 0 degrees, the viewing angle is based on a direction away from the first protrusion of the driving power supply line 1730 along the first inclined direction (the +Id1 direction) (i.e., line IV-IV′), which is perpendicular to the first chamfer line 1730cl1 in FIG. 11. As shown in FIG. 14, in the display apparatus according to an embodiment, luminance in the first pixel P1 decreases relatively rapidly as the viewing angle increases, as compared with a case in which the upper surface of the pixel electrode is approximately flat.

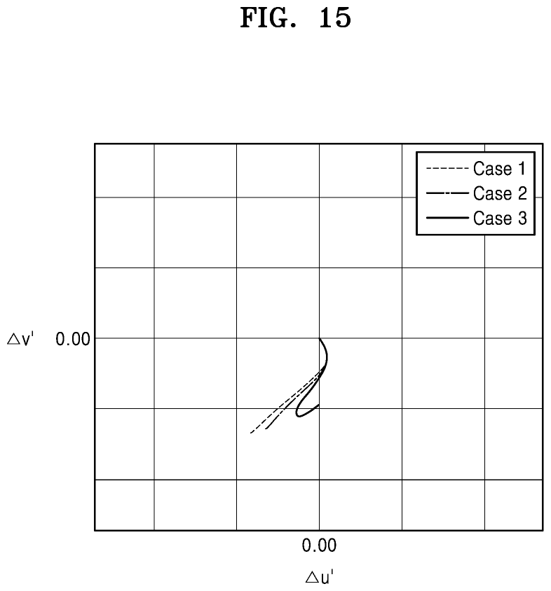

FIG. 15 is a graph schematically illustrating a change in color coordinates according to a change in viewing angle in a display apparatus according to a comparative example. Particularly, FIG. 15 is a graph for a case in which the upper surface of a pixel electrode is approximately flat for all pixels of the display apparatus, and is a graph in CIE 1976 color coordinates. The horizontal axis of FIG. 15 is Δu′, the vertical axis is Δv′, and coordinates of the center of the graph of FIG. 15 are (0.00, 0.00). In a graph as in FIG. 15, when the color coordinates move in the direction to the first quadrant, it means that the user recognizes yellow relatively more, when the color coordinates move to the second quadrant, it means that the user recognizes green relatively more, when the color coordinates move to the third quadrant, it means that the user recognizes blue relatively more, and when the color coordinates move to the fourth quadrant, it means that the user recognizes red relatively more.

As shown in FIG. 15, it may be understood that in Cases 1 and 2, the user recognizes blue relatively more as the viewing angle increases, and in Case 3, the user recognizes red relatively more as the viewing angle increases. In Case 3, a viewing angle increases based on a direction away from the protrusion of the driving power supply line 1730 protruding in the direction (the −x direction) opposite to the second direction, in the first inclined direction (the +Id1 direction) that forms approximately 45 degrees with the first direction (the +y direction) in which the data line 1710 extends. Cases 1 and 2 differ from Case 3 with respect to the direction in which the viewing angle increases.

The human eye is insensitive to blue but relatively sensitive to red. Accordingly, a change in color coordinates according to a change in the viewing angle as in Case 1 or 2 may hardly be recognized by a user of the display apparatus. However, a change in color coordinates according to a change in viewing angle as in Case 3 may be easily recognized by the user. Accordingly, when a change in color coordinates according to a change in the viewing angle as in Case 3 occurs in the display apparatus, the user may recognize that display quality of the display apparatus is not high.

In the display apparatus according to an embodiment, as described above, the 1^{st}-1^{st} distance d1-1 from the 1^{st}-1^{st} portion 211a1 of the first upper surface 211a of the first pixel electrode 211 to the upper surface of the substrate 100 may be greater than the 1^{st}-2^{nd} distance d1-2 from the 1^{st}-2^{nd} portion 211a2 of the first upper surface 211a to the upper surface of the substrate 100. In such an embodiment, the first upper surface 211a of the first pixel electrode 211 may have an inclined shape with respect to the substrate 100 between a center of the 1^{st}-1^{st} portion 211a1 and a center of the 1^{st}-2^{nd} portion 211a2. Accordingly, luminance in the first pixel P1 rapidly decreases, as described above with reference to FIG. 14, when the viewing angle increases based on a direction away from the first protrusion of the driving power supply line 1730 in the first inclined direction (the +Id1 direction) perpendicular to the first chamfer line 1730cl1, i.e., along line IV-IV′. When the first pixel P1 is a pixel that emits that emits red light, it means that the luminance of the red light rapidly decreases as the viewing angle increases in the corresponding direction. Accordingly, as in Case 3 of FIG. 15, the user may be effectively prevented from recognizing red relatively more as the viewing angle increases. Thus, a display apparatus that may be recognized by a user to display a high-quality image may be implemented.

In such an embodiment, in the second pixel P2, when viewed from the direction perpendicular to the substrate 100 (the z-axis direction), a second protrusion of the driving power supply line 1730 protruding in the second direction may not have a chamfered shape but have an approximately rectangular shape. The second protrusion may correspond to the second pixel electrode 212 positioned in the second pixel P2. In such an embodiment, a length of the second protrusion in the first direction (the +y direction) may be equal to a length, in the first direction (the +y direction), of a portion (or an exposed portion) of the second pixel electrode 212 which is not covered by the pixel-defining layer 125 but exposed by the second opening 125OP2 of the pixel-defining layer 125. In such an embodiment, an end of the second protrusion in the first direction (the +y direction) may correspond to (i.e., be aligned with) an end, in the first direction (the +y direction), of a portion of the second pixel electrode 212 which is not covered with the pixel-defining layer 125 but exposed by the second opening 125OP2 of the pixel-defining layer 125, and an end of the second protrusion in a direction (the −y direction) opposite to the first direction may correspond to (i.e., be aligned with) an end, in the direction (the −y direction) opposite to the first direction, of the portion of the second pixel electrode 212 which is not covered with the pixel-defining layer 125 but exposed by the second opening 125OP2 of the pixel-defining layer 125.

Accordingly, the portion of the second pixel electrode 212 exposed by the second opening 125OP2 of the pixel-defining layer 125 may have an approximately flat surface with respect to the upper surface of the substrate 100. As described above, the first pixel P1 may include a pixel that emits red light, and the second pixel P2 may include a pixel that emits green light or a pixel that emits blue light. In such an embodiment, in the second pixel P2, even when the viewing angle increases, a degree of decrease in luminance of the second pixel P2 recognized by the user is less than a degree of decrease in luminance of the first pixel P1, and thus, the user may recognize a high-quality image.

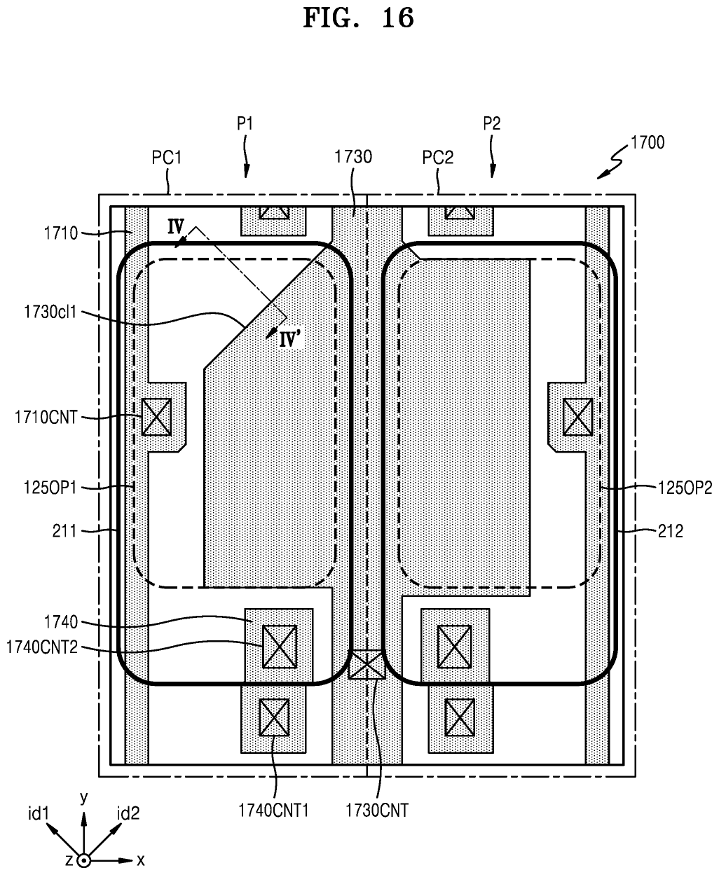

FIG. 16 is a plan view schematically illustrating some layers of a display apparatus according to an embodiment. As shown in FIG. 16, when viewed from the direction perpendicular to the substrate 100 (the z-axis direction), the length of the second protrusion in the first direction (the +y direction) may be greater than a length, in the first direction (the +y direction), of the portion of the second pixel electrode 212 which is not covered with the pixel-defining layer 125 but exposed by the second opening 125OP2 of the pixel-defining layer 125. In an embodiment, for example, an end of the second protrusion in the first direction (the +y direction) may correspond to (i.e., be aligned with) an end, in the first direction (the +y direction), of the portion of the second pixel electrode 212 which is not covered with the pixel-defining layer 125 but exposed by the second opening 125OP2 of the pixel-defining layer 125, but an end of the second protrusion in a direction (the −y direction) opposite to the first direction may be positioned outside of an end, in a direction (the −y direction) opposite to the first direction, of the portion of the second pixel electrode 212 which is not covered with the pixel-defining layer 125 but exposed by the second opening 125OP2 of the pixel-defining layer 125.

Accordingly, the portion of the second pixel electrode 212 exposed by the second opening 125OP2 of the pixel-defining layer 125 may have an approximately flat surface with respect to the upper surface of the substrate 100. As described above, the first pixel P1 may include a pixel that emits red light, and the second pixel P2 may include a pixel that emits green light or a pixel that emits blue light. In addition, in the second pixel P2, even when the viewing angle increases, a degree of decrease in luminance of the second pixel P2 recognized by the user is less than a degree of decrease in luminance of the first pixel P1, and thus, the user may recognize a high-quality image.

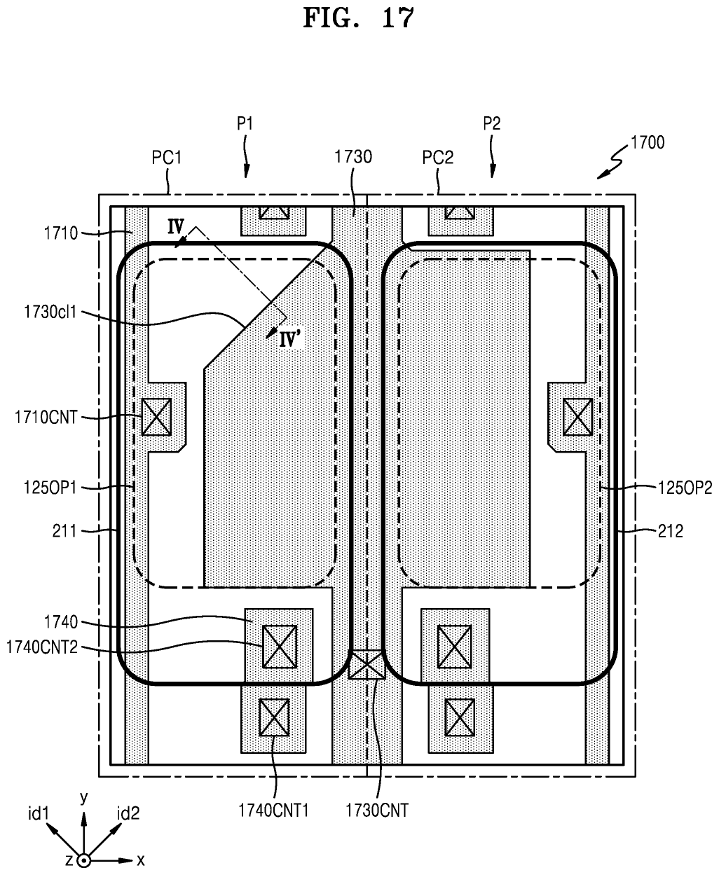

FIG. 17 is a plan view schematically illustrating some layers of a display apparatus according to an embodiment. As shown in FIG. 17, when viewed from the direction (the z-axis direction) perpendicular to the substrate 100, the length of the second protrusion in the first direction (the +y direction) may be greater than a length, in the first direction (the +y direction), of the portion of the second pixel electrode 212 which is not covered with the pixel-defining layer 125 but exposed by the second opening 125OP2 of the pixel-defining layer 125. In an embodiment, for example, an end of the second protrusion in the direction (the −y direction) opposite to the first direction may correspond to (i.e., be aligned with) an end, in the direction (the −y direction) opposite to the first direction, of the portion of the second pixel electrode 212 which is not covered with the pixel-defining layer 125 but exposed by the second opening 125OP2 of the pixel-defining layer 125, but an end of the second protrusion in the first direction (the +y direction) may be positioned outside of an end, in the first direction (the +y direction), of the portion of the second pixel electrode 212 which is not covered with the pixel-defining layer 125 but exposed by the second opening 125OP2 of the pixel-defining layer 125.

Accordingly, the portion of the second pixel electrode 212 exposed by the second opening 125OP2 of the pixel-defining layer 125 may have an approximately flat surface with respect to the upper surface of the substrate 100. As described above, the first pixel P1 may include a pixel that emits red light, and the second pixel P2 may include a pixel that emits green light or a pixel that emits blue light. In addition, in the second pixel P2, even when the viewing angle increases, a degree of decrease in luminance of the second pixel P2 recognized by the user is less than a degree of decrease in luminance of the first pixel P1, and thus, the user may recognize a high-quality image.

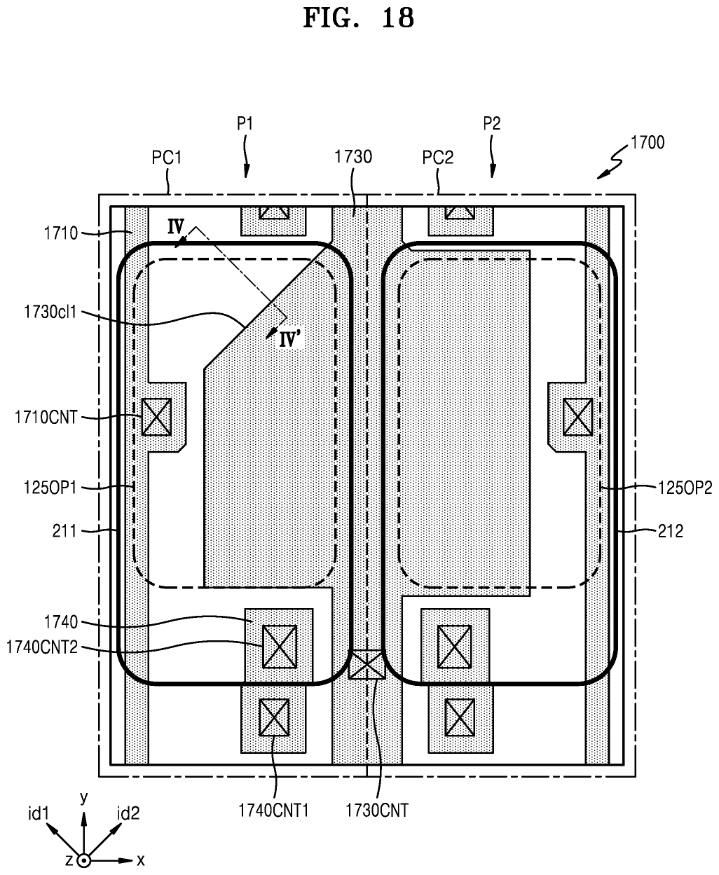

FIG. 18 is a plan view schematically illustrating some layers of a display apparatus according to an embodiment. As shown in FIG. 18, when viewed from the direction (the z-axis direction) perpendicular to the substrate 100, the length of the second protrusion in the first direction (the +y direction) may be greater than a length, in the first direction (the +y direction), of the portion of the second pixel electrode 212 which is not covered with the pixel-defining layer 125 but exposed by the second opening 125OP2 of the pixel-defining layer 125. In an embodiment, for example, an end of the second protrusion in the first direction (the +y direction) may be positioned outside of an end, in the first direction (the +y direction), of the portion of the second pixel electrode 212 which is not covered with the pixel-defining layer 125 but exposed by the second opening 125OP2 of the pixel-defining layer 125, and an end of the second protrusion in a direction (the −y direction) opposite to the first direction may be positioned outside of an end, in a direction (the −y direction) opposite to the first direction, of the portion of the second pixel electrode 212 which is not covered with the pixel-defining layer 125 but exposed by the second opening 125OP2 of the pixel-defining layer 125.

Accordingly, in such an embodiment, the portion of the second pixel electrode 212 exposed by the second opening 125OP2 of the pixel-defining layer 125 has an approximately flat surface with respect to the upper surface of the substrate 100. As described above, the first pixel P1 may include a pixel that emits red light, and the second pixel P2 may include a pixel that emits green light or a pixel that emits blue light. In addition, in the second pixel P2, even when the viewing angle increases, a degree of decrease in luminance of the second pixel P2 recognized by the user is less than a degree of decrease in luminance of the first pixel P1, and thus, the user may recognize a high-quality image.

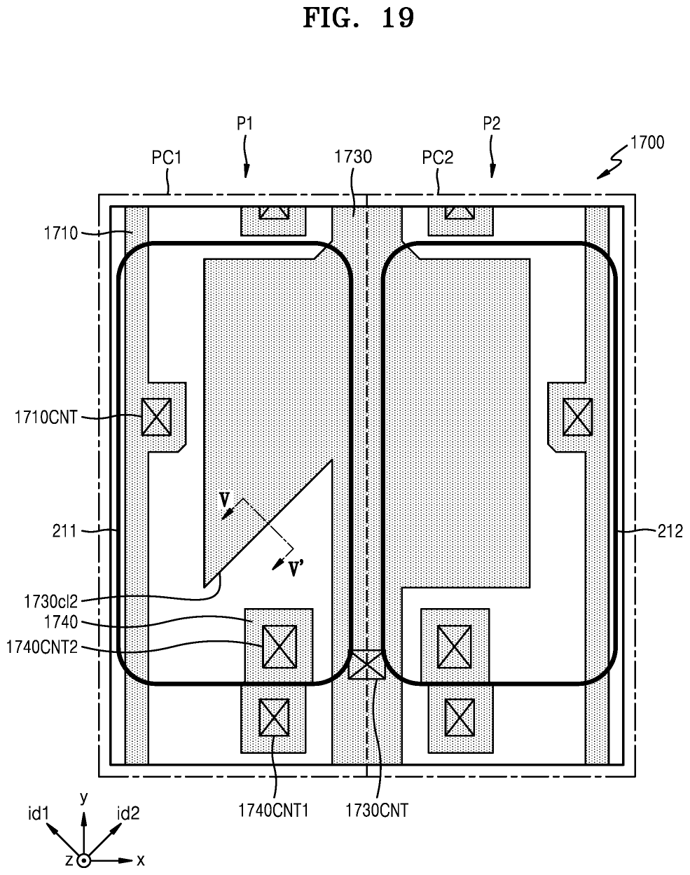

FIG. 19 is a plan view schematically illustrating some layers of a display apparatus according to an embodiment. As described above, in the display apparatus according to an embodiment shown in FIG. 19, when viewed from the direction perpendicular to the substrate 100 (the z-axis direction), in the first pixel P1, the driving power supply line 1730 may have a first protrusion in the direction (the −x direction) opposite to the second direction, and in the second pixel P2, the driving power supply line 1730 may have a second protrusion in the second direction (the +x direction). In such an embodiment, when viewed from the direction perpendicular to the substrate 100 (the z-axis direction), the second protrusion approximately has a rectangular shape, while the first protrusion has a shape of which a portion is chamfered. In an embodiment, for example, the first protrusion has a shape in which an end edge in a direction (the −Id1 direction) opposite to the first inclined direction, which is a direction between the second direction (the +x direction) and the direction (the −y direction) opposite to the first direction, is chamfered. Accordingly, the first protrusion may have a second chamfer line 1730cl2 extending in a second inclined direction (a +Id2 direction), which is approximately perpendicular to the first inclined direction (the +Id1 direction), and is a direction between the first direction (the +y direction) and the second direction (the +x direction).

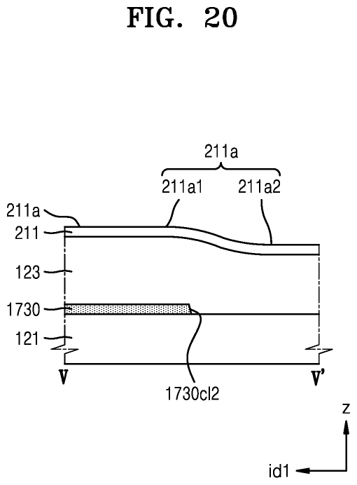

FIG. 20 is a cross-sectional view schematically illustrating a cross-section of the display apparatus shown in FIG. 19, taken along line V-V. As described above, when viewed from the direction perpendicular to the substrate 100 (the z-axis direction), the first protrusion positioned in the first pixel P1 has a shape in which an end edge in the direction (the −Id1 direction) opposite to the first inclined direction is chamfered, and may have the second chamfer line 1730cl2 extending in the second inclined direction (the +Id2 direction). Accordingly, as shown in FIG. 20, the second planarization layer 123 may have a gently (or gradually) inclined upper surface in an area adjacent to the second chamfer line 1730cl2 of the driving power supply line 1730. In addition, the first pixel electrode 211 in the first pixel P1 may have an inclined shape along a shape of the upper surface of the second planarization layer 123.

In such an embodiment, the first upper surface 211a of the first pixel electrode 211 may have a 1^{st}-1^{st} portion 211a1 and a 1^{st}-2^{nd} portion 211a2, where the 1^{st}-1^{st} portion 211a1 corresponds to the protrusion of the driving power supply line 1730, and the 1 st-2^{nd} portion 211a2 does not correspond to the protrusion of the driving power supply line 1730. This may be understood that, when viewed from the direction perpendicular to the substrate 100 (the z-axis direction), the protrusion of the driving power supply line 1730 corresponds to the 1^{st}-1^{st} portion 211a1 of the first upper surface 211a of the first pixel electrode 211, that is, the protrusion of the driving power supply line 1730 overlaps the 1^{st}-1^{st} portion 211a1 of the first upper surface 211a of the first pixel electrode 211. In addition, the protrusion of the driving power supply line 1730 may not overlap the 1^{st}-2^{nd} portion 211a2 of the first upper surface 211a of the first pixel electrode 211. Accordingly, a distance from the 1^{st}-1^{st} portion 211a1 of the first upper surface 211a of the first pixel electrode 211 to the upper surface of the substrate 100 may be greater than a distance from the 1^{st}-2^{nd} portion 211a2 of the first upper surface 211a to the upper surface of the substrate 100. In addition, the first upper surface 211a of the first pixel electrode 211 may have an inclined shape with respect to the substrate 100 between the center of the 1^{st}-1^{st} portion 211a1 and the center of the 1^{st}-2^{nd} portion 211a2.

When viewed from the direction perpendicular to the substrate 100 (the z-axis direction), the driving power supply line 1730 may have the second chamfer line 1730cl2 extending in a direction crossing a line connecting the central portion of the 1^{st}-1^{st} portion 211a1 and the central portion of the 1^{st}-2^{nd} portion 211a2. Accordingly, in the first upper surface 211a of the first pixel electrode 211, a virtual boundary between the 1^{st}-1^{st} portion 211a1 and the 1^{st}-2^{nd} portion 211a2 may correspond to the second chamfer line 1730cl2 of the first protrusion extending in the second inclined direction (the +Id2 direction). In addition, the line connecting the central portion of the 1^{st}-1^{st} portion 211a1 of the first pixel electrode 211 and the central portion of the 1^{st}-2^{nd} portion 211a2 of the first pixel electrode 211 may extend in the first inclined direction (the +Id1 direction) crossing the second chamfer line 1730cl2. In such an embodiment, as shown in FIG. 19, the line connecting the central portion of the 1^{st}-1^{st} portion 211a1 of the first pixel electrode 211 and the central portion of the 1^{st}-2^{nd} portion 211a2 of the first pixel electrode 211 extends in the first inclined direction (the +Id1 direction) perpendicular to the second chamfer line 1730cl2.

In such an embodiment, as shown in FIG. 19, the line connecting the central portion of the 1^{st}-1^{st} portion 211a1 of the first pixel electrode 211 and the central portion of the 1^{st}-2^{nd} portion 211a2 of the first pixel electrode 211 may form an acute angle with the first direction (the +y direction), in which the data line 1710 extends. In an embodiment, for example, as shown in FIG. 19, the line connecting the central portion of the 1^{st}-1^{st} portion 211a1 of the first pixel electrode 211 and the central portion of the 1^{st}-2^{nd} portion 211a2 of the first pixel electrode 211 may form about 45 degrees with the first direction (the +y direction), in which the data line 1710 extends. In such an embodiment, when viewed from the direction perpendicular to the substrate 100 (the z-axis direction), the central portion of the 1^{st}-2^{nd} portion 211a2 may be positioned farther from the data line 1710 than the central portion of the 1^{st}-1^{st} portion 211a1, and the central portion of the 1^{st}-2^{nd} portion 211a2 may be positioned in the direction (the −y direction) opposite to the first direction from the central portion of the 1^{st}-1^{st} portion 211a1.

Accordingly, in the display apparatus according to an embodiment, as described above, the distance from the 1^{st}-1^{st} portion 211a1 of the first upper surface 211a of the first pixel electrode 211 to the upper surface of the substrate 100 may be greater than the distance from the 1^{st}-2^{nd} portion 211a2 of the first upper surface 211a to the upper surface of the substrate 100. In addition, the first upper surface 211a of the first pixel electrode 211 may have an inclined shape with respect to the substrate 100 between the center of the 1^{st}-1^{st} portion 211a1 and the center of the 1^{st}-2^{nd} portion 211a2. Accordingly, luminance in the first pixel P1 rapidly decreases, as described above with reference to FIG. 14, when the viewing angle increases based on a direction away from the first protrusion of the driving power supply line 1730 in the first inclined direction (the +Id1 direction) perpendicular to the second chamfer line 1730cl2, i.e., along line V-V. In an embodiment where the first pixel P1 is a pixel that emits red light, the luminance of the red light rapidly decreases as the viewing angle increases in the corresponding direction. Accordingly, as described above with reference to Case 3 of FIG. 15, the user may be effectively prevented from recognizing red relatively more as the viewing angle increases. Thus, a display apparatus that may be recognized by a user to display a high-quality image may be implemented.

In such an embodiment, the features of the second pixel P2, are the same as those described above with reference to FIGS. 11 and 16 to 18, and any repetitive detailed description thereof will be omitted.

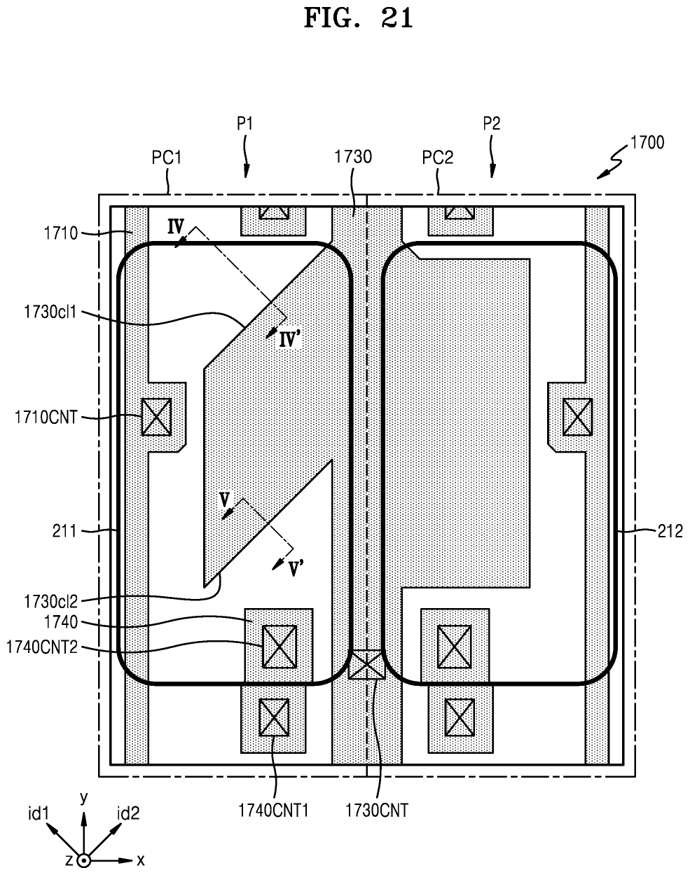

FIG. 21 is a plan view schematically illustrating some layers of a display apparatus according to an embodiment. As described above, in the display apparatus according to an embodiment shown in FIG. 21, in the first pixel P1, the driving power supply line 1730 may have a first protrusion in the direction (the −x direction) opposite to the second direction, and in the second pixel P2, the driving power supply line 1730 may have a second protrusion in the second direction (the +x direction). In addition, when viewed from the direction perpendicular to the substrate 100 (the z-axis direction), the second protrusion approximately has a rectangular shape, while the first protrusion has a shape of which a portion is chamfered.

In an embodiment, for example, in the first protrusion, an end edge in the first inclined direction (the +Id1 direction), which is a direction between the first direction (the +y direction) and the direction (the −x direction) opposite to the second direction, may have a chamfered shape, and an end edge in the direction (the −Id1 direction) opposite to the first inclined direction, which is a direction between the second direction (the +x direction) and the direction (the −y direction) opposite to the first direction, may have a chamfered shape. Accordingly, the first protrusion may have the first chamfer line 1730cl1 and the second chamfer line 1730cl2 each extending in a second inclined direction (a +Id2 direction), which is approximately perpendicular to the first inclined direction (the +Id1 direction), and is a direction between the first direction (the +y direction) and the second direction (the +x direction).

In the display apparatus according to an embodiment, as described above with reference to FIGS. 11, 13, 19, and 20, the first pixel P1 emits red light, such that the user may be prevented from recognizing red relatively more as the viewing angle increases. Thus, a display apparatus that may be recognized by a user to display a high-quality image may be implemented.

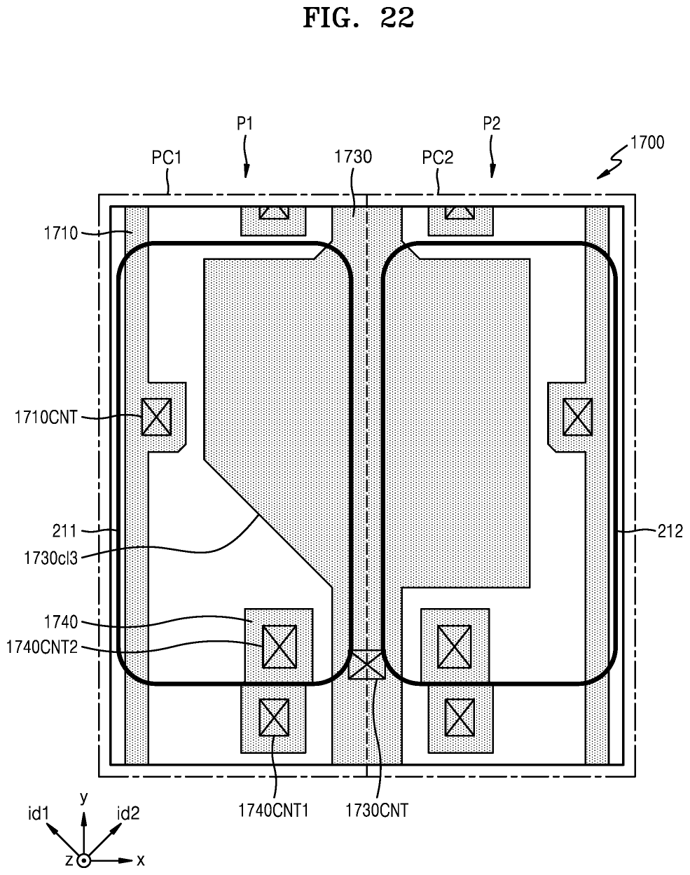

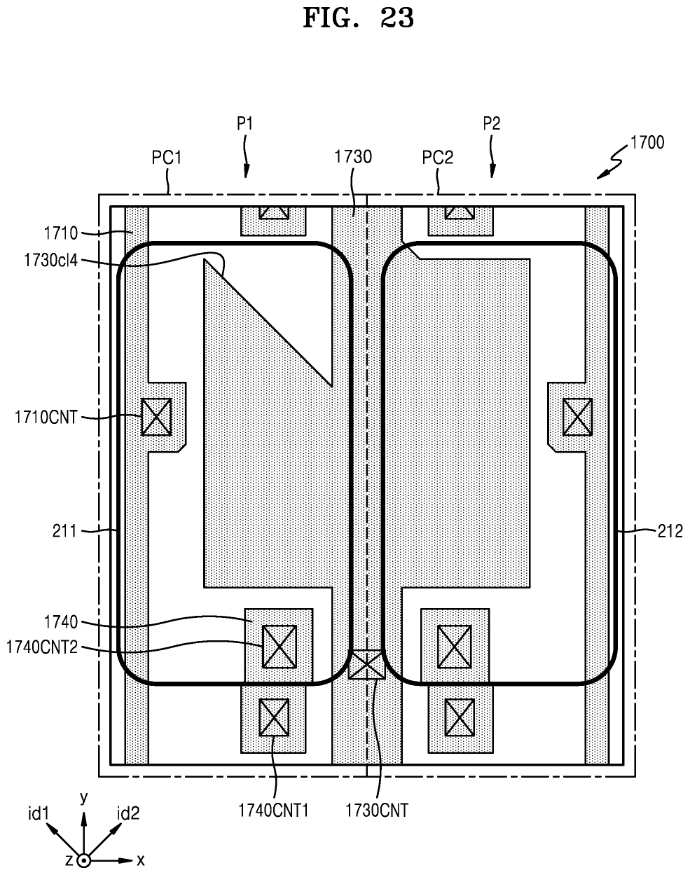

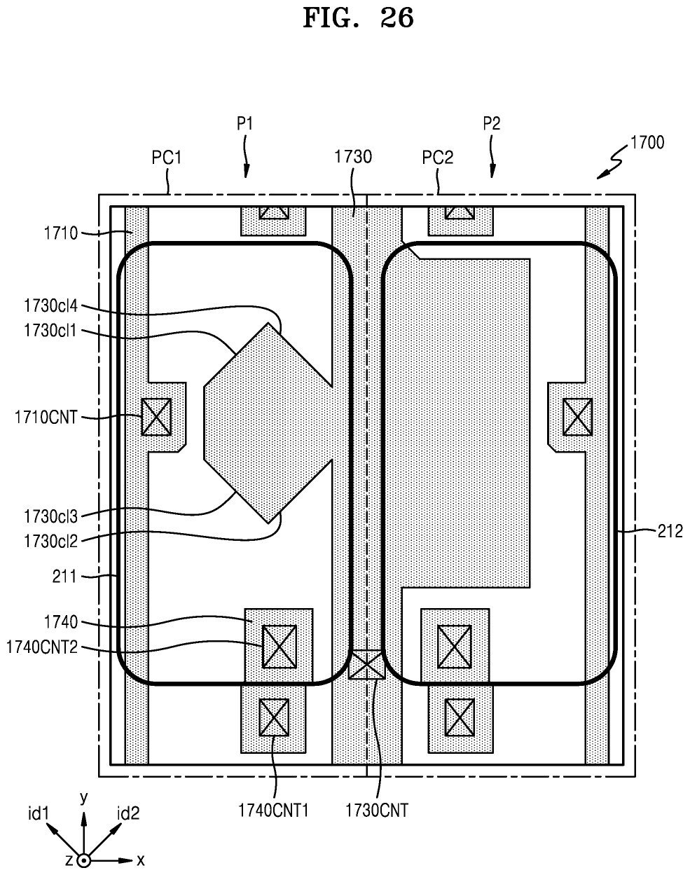

In such an embodiment, the features of the second pixel P2, are the same as those described above with reference to FIGS. 11 and 16 to 18, and any repetitive detailed description thereof will be omitted. This is true in the embodiments to be described later with reference to FIGS. 22 and 26 and modifications thereof.

Embodiments in which, when viewed from the direction perpendicular to the substrate 100 (the z-axis direction), in the first pixel P1, the first protrusion of the driving power supply line 1730 that protrudes in the direction (the −x direction) opposite to the first chamfer line 1730cl1 and/or the second chamfer line 1730cl2 each extending in the second inclined direction (the +Id2 direction) is described above. However, the present disclosure is not limited thereto.

In an embodiment, for example, as shown in FIG. 22 that is a plan view schematically illustrating some layers of the display apparatus according to an embodiment, in the first protrusion positioned in the first pixel P1, an end edge in the direction (the −Id2 direction) opposite to the second inclined direction, which is a direction between the direction (the −y direction) opposite to the first direction and the direction (the −Id2 direction) opposite to the second direction, may have a chamfered shape. Accordingly, the first protrusion may have a third chamfer line 1730cl3 extending in the first inclined direction (the +Id1 direction), which is a direction between the first direction (the +y direction) and the direction (the −x direction) opposite to the second direction.

In some embodiments, as shown in FIG. 22 that is a plan view schematically illustrating some layers of the display apparatus according to an embodiment, in the first protrusion positioned in the first pixel P1, an end edge in the second inclined direction (the +Id2 direction), which is a direction between the first direction (the +y direction) and the second direction (the +x direction), may have a chamfered shape. Accordingly, the first protrusion may have a fourth chamfer line 1730cl4 extending in the first inclined direction (the +Id1 direction), which is a direction between the first direction (the +y direction) and the direction (the −x direction) opposite to the second direction.

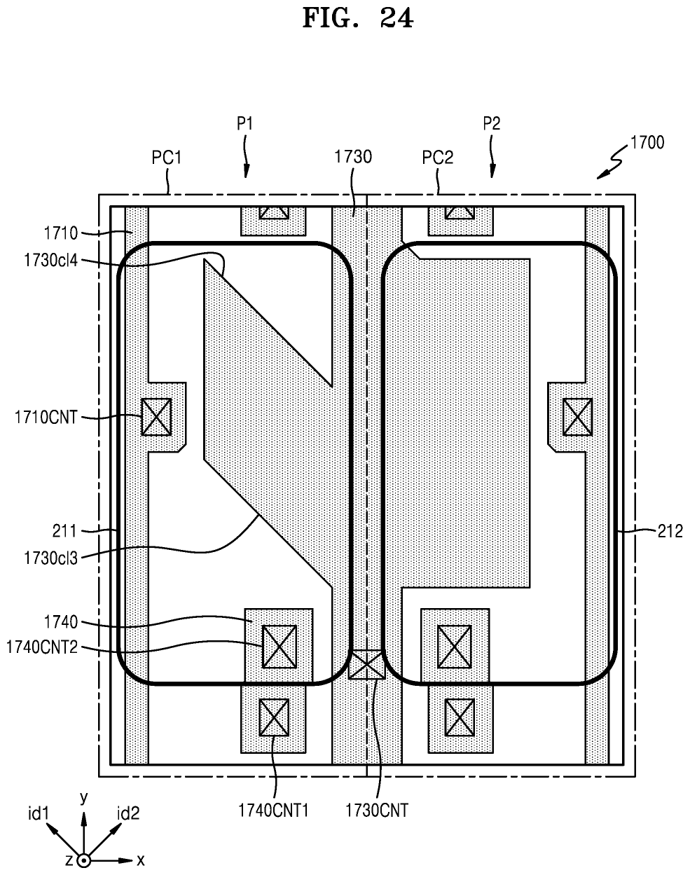

Alternatively, as shown in FIG. 24 that is a plan view schematically illustrating some layers of the display apparatus according to an embodiment, the first protrusion positioned in the first pixel P1 may have a third chamfer line 1730cl3 and a fourth chamfer line 1730cl4 each extending in the first inclined direction (the +Id1 direction), which is a direction between the first direction (the +y direction) and the direction (the −x direction) opposite to the second direction.

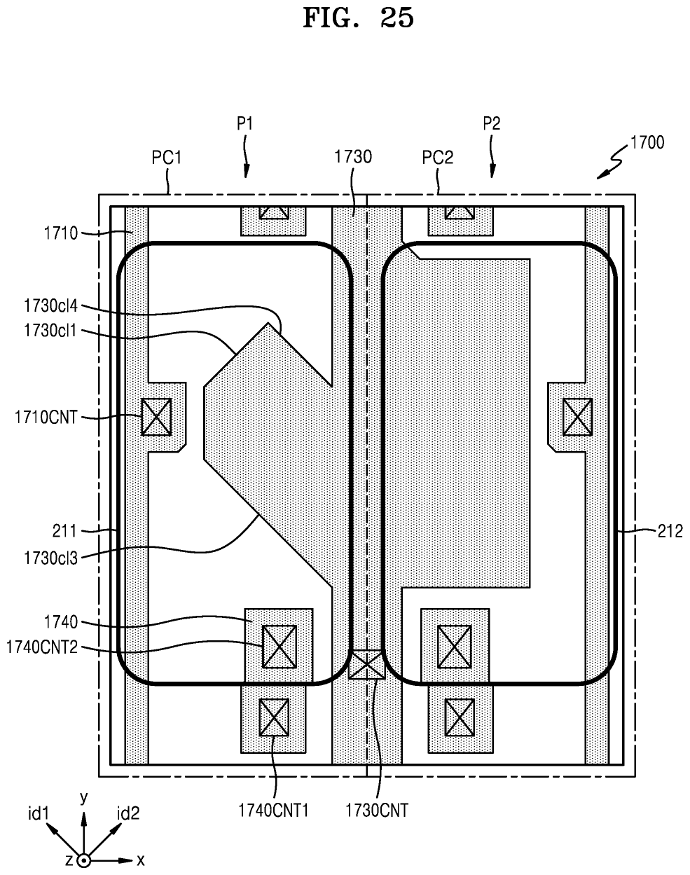

In some embodiments, as shown in FIG. 25 that is a plan view schematically illustrating some layers of the display apparatus according to an embodiment, the first protrusion positioned in the first pixel P1 may have the third chamfer line 1730cl3 and the fourth chamfer line 1730cl4 each extending in the first inclined direction (the +Id1 direction), which is a direction between the first direction (the +y direction) and the direction (the −x direction) opposite to the second direction, and the first chamfer line 1730cl1 extending in the second inclined direction (the +Id2 direction), which is a direction between the first direction (the +y direction) and the second direction (the +x direction).

In some embodiments, as shown in FIG. 26 that is a plan view schematically illustrating some layers of the display apparatus according to an embodiment, the first protrusion positioned in the first pixel P1 may have the third chamfer line 1730cl3 and the fourth chamfer line 1730cl4 each extending in the first inclined direction (the +Id1 direction), which is a direction between the first direction (the +y direction) and the direction (the −x direction) opposite to the second direction, and may have the first chamfer line 1730cl1 and the second chamfer line 1730cl2 each extending in the second inclined direction (the +Id2 direction), which is a direction between the first direction (the +y direction) and the second direction (the +x direction).

In an embodiment, as shown in the drawings, an edge of a chamfered portion of the first protrusion positioned in the first pixel P1 and an edge of other portions are shown as having a sharp shape, but the disclosure is not limited thereto. In an alternative embodiment, for example, a portion at which the edge of the chamfered shape of the first protrusion meets the edge of a portion adjacent thereto may not have a sharp shape having a certain angle, but may form a curve.

According to embodiments as described above, a display apparatus on which a viewer may view a high-quality image may be implemented. However, the invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a substrate; and
a first pixel electrode disposed over the substrate,
wherein a distance from a first portion of an upper surface of the first pixel electrode to an upper surface of the substrate is greater than a distance from a second portion of the upper surface of the first pixel electrode to the upper surface of the substrate.

2. The display apparatus of claim 1, further comprising:
a data line disposed over the substrate and extending in a first direction; and
an insulation layer covering the data line,
wherein the first pixel electrode is disposed over the insulation layer, and,
when viewed from a direction perpendicular to the substrate, a line connecting a central portion of the first portion of the upper surface of the first pixel electrode and a central portion of the second portion of the upper surface of the first pixel electrode forms an acute angle with the first direction.

3. The display apparatus of claim 2, wherein, when viewed from the direction perpendicular to the substrate, the line connecting the central portion of the first portion of the upper surface of the first pixel electrode and the central portion of the second portion of the upper surface of the first pixel electrode forms an angle of about 45 degrees with the first direction.

4. The display apparatus of claim 2, wherein, when viewed from the direction perpendicular to the substrate, the central portion of the second portion of the upper surface of the first pixel electrode is positioned closer to the data line than the central portion of the first portion of the upper surface of the first pixel electrode, and the central portion of the second portion of the upper surface of the first pixel electrode is positioned in the first direction from the central portion of the first portion of the upper surface of the first pixel electrode.

5. The display apparatus of claim 2, further comprising:
a first conductive layer disposed on a layer on which the data line is disposed,
wherein the insulation layer covers the first conductive layer, and,
when viewed from the direction perpendicular to the substrate, the first conductive layer corresponds to the first portion of the upper surface of the first pixel electrode.

6. The display apparatus of claim 5, wherein, when viewed from the direction perpendicular to the substrate, the first conductive layer does not overlap the second portion of the upper surface of the first pixel electrode.

7. The display apparatus of claim 5, wherein, when viewed from the direction perpendicular to the substrate, the first conductive layer has a chamfered line extending in a direction crossing the line connecting the central portion of the first portion of the upper surface of the first pixel electrode and the central portion of the second portion of the upper surface of the first pixel electrode to each other.

8. The display apparatus of claim 7, wherein, when viewed from the direction perpendicular to the substrate, the chamfered line is perpendicular to the line connecting the central portion of the first portion of the upper surface of the first pixel electrode and the central portion of the second portion of the upper surface of the first pixel electrode to each other.

9. The display apparatus of claim 1, further comprising:
a data line disposed over the substrate and extending in a first direction;
an insulation layer covering the data line;
a second pixel electrode disposed over the insulation layer; and
a pixel-defining layer covering an edge of each of the first pixel electrode and the second pixel electrode,
wherein the first pixel electrode is disposed over the insulation layer, and,
when viewed from a direction perpendicular to the substrate, a line connecting a central portion of the first portion of the upper surface of the first pixel electrode and a central portion of the second portion of the upper surface of the first pixel electrode forms an acute angle with the first direction.

10. The display apparatus of claim 9, further comprising:
a first conductive layer and a second conductive layer disposed on a layer on which the data line is disposed, wherein the insulation layer covers the first conductive layer and the second conductive layer, and,
when viewed from the direction perpendicular to the substrate, the first conductive layer corresponds to the first portion of the upper surface of the first pixel electrode, and the second conductive layer corresponds to the second pixel electrode.

11. The display apparatus of claim 10, wherein, when viewed from the direction perpendicular to the substrate, the first conductive layer does not overlap the second portion of the upper surface of the first pixel electrode, and a length of the second conductive layer in the first direction is equal to a length, in the first direction, of an exposed portion of the second pixel electrode, which is not covered with the pixel-defining layer.

12. The display apparatus of claim 10, wherein, when viewed from the direction perpendicular to the substrate, the first conductive layer does not overlap the second portion of the upper surface of the first pixel electrode, and an end of the second conductive layer in the first direction is aligned with an end, in the first direction, of an exposed portion of the second pixel electrode, which is not covered with the pixel-defining layer, and an end of the second conductive layer in a direction opposite to the first direction is aligned with an end, in the direction opposite to the first direction, of the exposed portion of the second pixel electrode, which is not covered with the pixel-defining layer.

13. The display apparatus of claim 10, wherein, when viewed from the direction perpendicular to the substrate, the first conductive layer does not overlap the second portion of the upper surface of the first pixel electrode, and a length of the second conductive layer in the first direction is greater than a length, in the first direction, of an exposed portion of the second pixel electrode, which is not covered with the pixel-defining layer.

14. The display apparatus of claim 10, wherein, when viewed from the direction perpendicular to the substrate, the first conductive layer does not overlap the second portion of the upper surface of the first pixel electrode, and an end of the second conductive layer in the first direction is aligned with an end, in the first direction, of an exposed portion of the second pixel electrode, which is not covered with the pixel-defining layer, and an end of the second conductive layer in a direction opposite to the first direction is positioned outside of an end, in the direction opposite to the first direction, of the exposed portion of the second pixel electrode, which is not covered with the pixel-defining layer.

15. The display apparatus of claim 10, wherein, when viewed from the direction perpendicular to the substrate, the first conductive layer does not overlap the second portion of the upper surface of the first pixel electrode, and an end of the second conductive layer in the first direction is positioned outside of an end, in the first direction, of an exposed portion of the second pixel electrode, which is not covered with the pixel-defining layer, and an end of the second conductive layer in a direction opposite to the first direction is aligned with an end, in the direction opposite to the first direction, of the exposed portion of the second pixel electrode, which is not covered with the pixel-defining layer.

16. The display apparatus of claim 10, wherein, when viewed from the direction perpendicular to the substrate, the first conductive layer does not overlap the second portion of the upper surface of the first pixel electrode, and an end of the second conductive layer in the first direction is positioned outside of an end, in the first direction, of an exposed portion of the second pixel electrode, which is not covered with the pixel-defining layer, and an end of the second conductive layer in a direction opposite to the first direction is positioned outside of an end, in the direction opposite to the first direction, of the exposed portion of the second pixel electrode, which is not covered with the pixel-defining layer.

17. The display apparatus of claim 10, wherein, when viewed from the direction perpendicular to the substrate, the first conductive layer has a chamfered line extending in a direction crossing the line connecting the central portion of the first portion of the upper surface of the first pixel electrode and the central portion of the second portion of the upper surface of the first pixel electrode.

18. The display apparatus of claim 17, wherein, when viewed from the direction perpendicular to the substrate, the chamfered line is perpendicular to the line connecting the central portion of the first portion of the upper surface of the first pixel electrode and the central portion of the second portion of the upper surface of the first pixel electrode.

19. The display apparatus of claim 10, wherein, when viewed from the direction perpendicular to the substrate, the line connecting the central portion of the first portion of the upper surface of the first pixel electrode and the central portion of the second portion of the upper surface of the first pixel electrode forms an angle of about 45 degrees with the first direction.

20. The display apparatus of claim 10, wherein, when viewed from the direction perpendicular to the substrate, the central portion of the second portion of the upper surface of the first pixel electrode is positioned closer to the data line than the central portion of the first portion of the upper surface of the first pixel electrode, and the central portion of the second portion of the upper surface of the first pixel electrode is positioned in the first direction from the central portion of the first portion of the upper surface of the first pixel electrode.
